(19) United States
(12) Patent Application Publication
(10) Pub. No.: US 2023/0244152 A1
(43) Pub. Date: Aug. 3, 2023

(54) SYSTEMS, METHODS, AND PRODUCTS FOR DETERMINING PRINTING PROBABILITY OF ASSIST FEATURE AND ITS APPLICATION

(71) Applicant: ASML NETHERLANDS B.V., Veldhoven (NL)

(72) Inventors: Jen-Shiang WANG, Sunnyvale, CA (US); Pengcheng YANG, Shenzhen (CN); Jiao HUANG, Shenzhen (CN); Yen-Wen LU, Saratoga, CA (US); Liang LIU, Shenzhen (CN); Chen ZHANG, San Jose, CA (US)

(73) Assignee: ASML NETHERLANDS B.V., Veldhoven (NL)

(21) Appl. No.: 18/008,075

(22) PCT Filed: Jun. 17, 2021
(86) PCT No.: PCT/EP2021/066323

§ 371 Date: Dec. 2, 2022

(30) Foreign Application Priority Data
Jun. 24, 2020 (WO) PCT/CN2020/098166

(51) Int. Cl. G03F 7/00; G03F 1/70; G03F 7/105

(52) U.S. Cl. CPC G03F 7/706843; G03F 1/70; G03F 7/705; G03F 7/105

(57) ABSTRACT

A method for determining a likelihood that an assist feature of a mask pattern will print on a substrate. The method includes obtaining (i) a plurality of images of a pattern printed on a substrate and (ii) variance data the plurality of images of the pattern; determining, based on the variance data, a model configured to generate variance data associated with the mask pattern; and determining, based on model-generated variance data for a given mask pattern and a resist image or etch image associated with the given mask pattern, the likelihood that an assist feature of the given mask pattern will be printed on the substrate. The likelihood can be applied to adjust one or more parameters related to a patterning process or a patterning apparatus to reduce the likelihood that the assist feature will print on the substrate.

### CROSS-REFERENCE TO RELATED APPLICATIONS

This application claims priority of PCT application PCT/CN2020/098166 which was filed on Jun. 24, 2020 and which is incorporated herein in its entirety by reference.

### TECHNICAL FIELD

The description herein relates to lithographic apparatuses and patterning processes, and more particularly method for determining printing of features of a patterning device and improvements related to a patterning process.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g. comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a wafer stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, microlithography is a central step in the manufacturing of ICs, where patterns formed on substrates define functional elements of the ICs, such as microprocessors, memory chips etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source). This process in which features with dimensions smaller than the classical resolution limit of a lithographic projection apparatus are printed, is commonly known as low-k₁ lithography, according to the resolution formula CD=k₁×λ/NA, where is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

In an embodiment, there is provided a method for determining a likelihood that an assist feature of a mask pattern will print on a substrate. The method includes obtaining (i) a plurality of images of a pattern printed on a substrate, the images having been formed using the mask pattern and (ii) variance data associated with pixels of the plurality of images of the pattern; determining, based on the variance data, a model configured to generate variance data associated with the mask pattern; and determining, based on model-generated variance data for a given mask pattern and a resist image or etch image associated with the given mask pattern, the likelihood that an assist feature of the given mask pattern will be printed on the substrate, the likelihood being applied to adjust one or more parameters related to a patterning process or a patterning apparatus to reduce the likelihood that the assist feature will print on the substrate.

Furthermore, in an embodiment, there is provided a method for generating a model associated with a mask pattern. The method includes obtaining (i) a plurality of images of a pattern printed on a substrate using the mask pattern, and (iii) variance data associated with each pixel of the plurality of images of the pattern; and generating, based on the variance data, a model configured to predict variance data associated with the mask pattern, the variance data being used to determine a likelihood that an assist feature of the mask pattern will print on the substrate.

Furthermore, in an embodiment, there is provided a method for generating optical proximity correction data for a mask pattern. The method includes obtaining (i) a mask image or an aerial image associated with the mask pattern, and (ii) a resist image associated with the mask pattern; executing a model configured to predict variance data associated with the mask pattern, the model using the mask image or the aerial image to predict the variance data; determining, based on the variance data and the resist image, a likelihood that an assist feature of the mask pattern will print on a substrate; and generating, based on the likelihood that the assist feature will print, the optical proximity correction (OPC) data for modifying one or more main features, or one or more assist features of the mask pattern.

Furthermore, in an embodiment, there is provided a non-transitory computer-readable media comprising instructions that, when executed by one or more processors, cause operations includes obtaining (i) a plurality of images of a pattern printed on a substrate, the images having been formed using a mask pattern and (ii) variance data associated with pixels of the plurality of images of the pattern; determining, based on the variance data, a model configured to generate variance data associated with the mask pattern; and determining, based on model-generated variance data for a given mask pattern and a resist image or etch image associated with the given mask pattern, a likelihood that an assist feature of the given mask pattern will be printed on the substrate, the likelihood being applied to adjust one or more parameters related to a patterning process or a patterning apparatus to reduce the likelihood that the assist feature will print on the substrate.

Furthermore, in an embodiment, there is provided a non-transitory computer-readable media comprising instructions that, when executed by one or more processors, cause operations includes obtaining (i) a plurality of images of a pattern printed on a substrate using a mask pattern, and (iii) variance data associated with each pixel of the plurality of images of the pattern; and generating, based on the variance data, a model configured to predict variance data associated with the mask pattern, the variance data being used to determine a likelihood that an assist feature of the mask pattern will print on the substrate.

Furthermore, in an embodiment, there is provided a non-transitory computer-readable media comprising instructions that, when executed by one or more processors, cause operations includes obtaining (i) a mask image or an aerial image associated with the mask pattern, and (ii) a resist image associated with a mask pattern; executing a model configured to predict variance data associated with the mask pattern, the model using the mask image or the aerial image to predict the variance data; determining, based on the variance data and the resist image, a likelihood that an assist feature of the mask pattern will print on a substrate; and generating, based on the likelihood that the assist feature will print, optical proximity correction (OPC) data for modifying one or more main features, or one or more assist features of the mask pattern.

Furthermore, in an embodiment, there is provided a non-transitory computer-readable media comprising instructions for generating a printability map associated with a mask pattern that, the computer-readable media when executed by one or more processors, cause operations includes obtaining (i) a plurality of images of a patterned substrate, (ii) a plurality of refined images based on the plurality of images, and (iii) a simulated refined image based on the mask pattern; marking each of the plurality of images based on the plurality of the refined images, the simulated refined image, and an intensity of pixels within each of the plurality of images; and generating, based on the markings, the printability map associated with the mask pattern.

Furthermore, in an embodiment, there is provided a method for generating one or more parameters of a patterning process. The method includes obtaining (i) a plurality of images of a patterned substrate, (ii) a plurality of refined images based on the plurality of images, and (iii) a simulated refined image based on the mask pattern; marking each of the plurality of images based on the plurality of the refined images, the simulated refined image, and an intensity of pixels within each of the plurality of images; and generating, based on the markings, the printability map associated with the mask pattern.

Furthermore, in an embodiment, there is provided a method for generating a printability map associated with a mask pattern. The method includes obtaining a plurality of binary images of a patterned substrate based on features of the mask pattern; aligning the plurality of binary images and summing intensities of the plurality of binary images; and dividing the summed image intensities by the total number of binary images to generate the printability map associated with the mask pattern, wherein each pixel intensity of the printability map is indicative of a probability that a feature of the mask pattern will print on a substrate.

Furthermore, in an embodiment, there is provided a non-transitory computer-readable media comprising instructions for generating a printability map associated with a mask pattern that, the computer-readable media when executed by one or more processors, cause operations includes obtaining a plurality of binary images of a patterned substrate based on features of the mask pattern; aligning the plurality of binary images and summing intensities of the plurality of binary images; and dividing the summed image intensities by the total number of binary images to generate the printability map associated with the mask pattern, wherein each pixel intensity of the printability map is indicative of a probability that a feature of the mask pattern will print on a substrate.

### BRIEF DESCRIPTION OF THE DRAWINGS

Embodiments will now be described, by way of example only, with reference to the accompanying drawings in which:

FIG. 1 is a block diagram of various subsystems of a lithography system, according to an embodiment;

FIG. 2 is a block diagram of simulation models corresponding to the subsystems in FIG. 1, according to an embodiment;

FIG. 3A is a flow chart of a process for determining a likelihood that an assist feature of a mask pattern may print on a substrate, according to an embodiment;

FIG. 3B is a flow chart of a process for determining of the likelihood that the assist feature of a given mask pattern may print on the substrate, according to an embodiment;

FIG. 3C is a flow chart of a process for establishing a correlation between the model-generated variance data (in FIG. 3A) and the resist image, according to an embodiment;

FIGS. 4A and 4C illustrate exemplary average data obtained from SEM images of a first pattern and a second pattern, respectively, according to an embodiment;

FIGS. 4B and 4D illustrate exemplary variance data obtained from SEM images of a first pattern and a second pattern, respectively, according to an embodiment;

FIG. 5 illustrates exemplary correlation between resist image intensity data and variance data determined e.g., in FIG. 3A, according to an embodiment;

FIG. 6A shows exemplary image of a resist pattern imaged on a substrate, according to an embodiment;

FIG. 6B is plot of exemplary variance data and resist image intensity data of FIG. 6A, according to an embodiment;

FIG. 7A shows another exemplary image of a resist pattern imaged on a substrate, according to an embodiment;

FIG. 7B is plot of another exemplary variance data and resist image intensity data of FIG. 7A, according to an embodiment;

FIG. 8A shows yet another exemplary image of a resist pattern imaged on a substrate, according to an embodiment;

FIG. 8B is plot of yet another exemplary variance data and resist image intensity data of FIG. 8A, according to an embodiment;

FIG. 9A shows yet another exemplary image of a resist pattern imaged on a substrate, according to an embodiment;

FIG. 9B is plot of yet another exemplary variance data and resist image intensity data of FIG. 9A, according to an embodiment;

FIG. 10 is a flow chart of a process for generating a model associated with a mask pattern to determine variance data associated with the mask pattern, according to an embodiment;

FIG. 11 is a flow chart of a process for generating optical proximity correction data for a mask pattern, according to an embodiment;

FIG. 12A is a flow chart of a process for generating a printability map, according to an embodiment;

FIG. 12B is another flow chart of a process for generating a printability map, according to an embodiment;

FIG. 12C is yet another flow chart of a process for generating a printability map, according to an embodiment;

FIG. 13 illustrates an exemplary raw SEM image of patterned substrate, a denoised SEM image of the raw SEM image, a refined SEM image of the raw SEM image, according to an embodiment;

FIG. 14 illustrates a simulated image associated with a mask pattern, a ridge highlighted image of the simulated image, and a simulated refined image of the simulated image, according to an embodiment;

FIG. 15A illustrates an exemplary segmentation of a SEM image of FIG. 13 and another refined image related to the segmented image, according to an embodiment,

FIG. 15B illustrate an exemplary printability map determined based on refined images of FIG. 15A, according to an embodiment;

FIG. 16 schematically depicts an embodiment of a scanning electron microscope (SEM), according to an embodiment;

FIG. 17 schematically depicts an embodiment of an electron beam inspection apparatus, according to an embodiment;

FIG. 18 is a flow diagram illustrating aspects of an example methodology of joint optimization, according to an embodiment;

FIG. 19 shows an embodiment of another optimization method, according to an embodiment;

FIGS. 20A, 20B and 21 show example flowcharts of various optimization processes, according to an embodiment;

FIG. 22 is a block diagram of an example computer system, according to an embodiment;

FIG. 23 is a schematic diagram of a lithographic projection apparatus, according to an embodiment;

FIG. 24 is a schematic diagram of another lithographic projection apparatus, according to an embodiment;

FIG. 25 is a more detailed view of the apparatus in FIG. 24, according to an embodiment;

FIG. 26 is a more detailed view of the source collector module SO of the apparatus of FIGS. 24 and 25, according to an embodiment.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range 5-20 nm).

The term “optimizing” and “optimization” as used herein mean adjusting a lithographic projection apparatus such that results and/or processes of lithography have more desirable characteristics, such as higher accuracy of projection of design layouts on a substrate, larger process windows, etc.

Further, the lithographic projection apparatus may be of a type having two or more substrate tables (and/or two or more patterning device tables). In such “multiple stage” devices the additional tables may be used in parallel, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above comprises or can form design layouts. The design layouts can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. The design rule limitations are typically referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

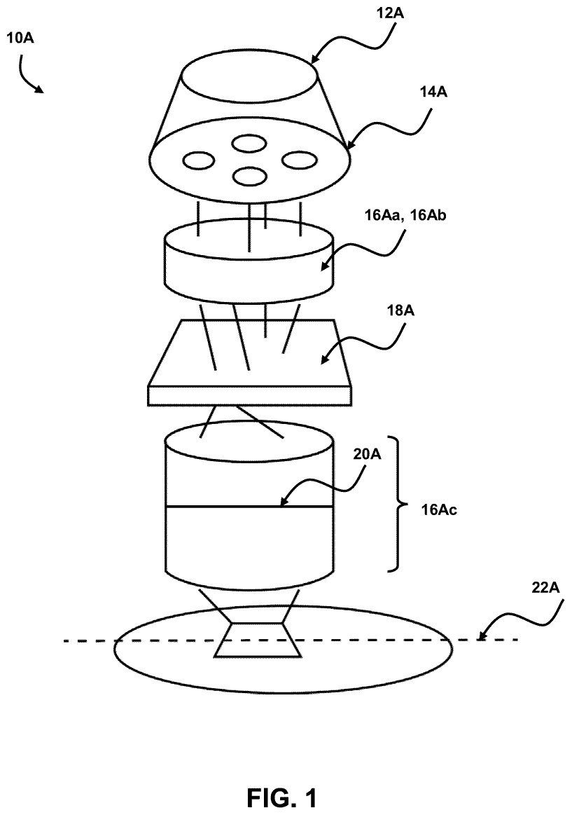

As a brief introduction, FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which define the partial coherence (denoted as sigma) and which may include optics 14A, 16Aa and 16Ab that shape radiation from the source 12A; a patterning device 14A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=sin(θₘₐₓ).

In an optimization process of a system, a figure of merit of the system can be represented as a cost function. The optimization process boils down to a process of finding a set of parameters (design variables) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations (i.e., worst deviation). The term “evaluation points” herein should be interpreted broadly to include any characteristics of the system. The design variables of the system can be confined to finite ranges and/or be interdependent due to practicalities of implementations of the system. In case of a lithographic projection apparatus, the constraints are often associated with physical properties and characteristics of the hardware such as tunable ranges, and/or patterning device manufacturability design rules, and the evaluation points can include physical points on a resist image on a substrate, as well as non-physical characteristics such as dose and focus.

In a lithographic projection apparatus, a source provides illumination (i.e. light); projection optics direct and shapes the illumination via a patterning device and onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in commonly assigned U.S. patent application Ser. No. 12/315,849, disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

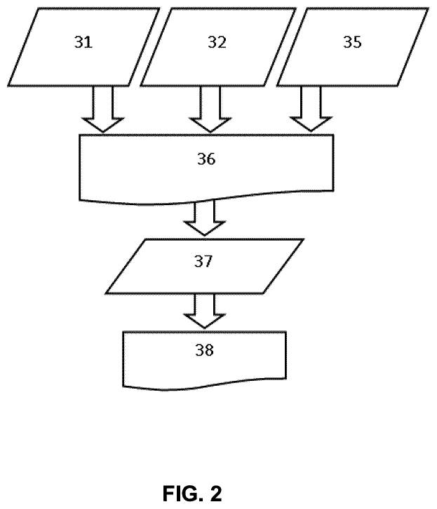

An exemplary flow chart for simulating lithography in a lithographic projection apparatus is illustrated in FIG. 2. A source model 31 represents optical characteristics (including radiation intensity distribution and/or phase distribution) of the source. A projection optics model 32 represents optical characteristics (including changes to the radiation intensity distribution and/or the phase distribution caused by the projection optics) of the projection optics. A design layout model 35 represents optical characteristics (including changes to the radiation intensity distribution and/or the phase distribution caused by a given design layout 33) of a design layout, which is the representation of an arrangement of features on or formed by a patterning device. An aerial image 36 can be simulated from the design layout model 35, the projection optics model 32 and the design layout model 35. A resist image 38 can be simulated from the aerial image 36 using a resist model 37. Simulation of lithography can, for example, predict contours and CDs in the resist image.

More specifically, it is noted that the source model 31 can represent the optical characteristics of the source that include, but not limited to, NA-sigma (σ) settings as well as any particular illumination source shape (e.g. off-axis radiation sources such as annular, quadrupole, and dipole, etc.). The projection optics model 32 can represent the optical characteristics of the of the projection optics that include aberration, distortion, refractive indexes, physical sizes, physical dimensions, etc. The design layout model 35 can also represent physical properties of a physical patterning device, as described, for example, in U.S. Pat. No. 7,587,704, which is incorporated by reference in its entirety. The objective of the simulation is to accurately predict, for example, edge placements, aerial image intensity slopes and CDs, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). As will be appreciated by those skilled in the art, these patterns or clips represent small portions (i.e. circuits, cells or patterns) of the design and especially the clips represent small portions for which particular attention and/or verification is needed. In other words, clips may be the portions of the design layout or may be similar or have a similar behavior of portions of the design layout where critical features are identified either by experience (including clips provided by a customer), by trial and error, or by running a full-chip simulation. Clips usually contain one or more test patterns or gauge patterns.

An initial larger set of clips may be provided a priori by a user based on known critical feature areas in a design layout which require particular image optimization. Alternatively, in another embodiment, the initial larger set of clips may be extracted from the entire design layout by using some kind of automated (such as, machine vision) or manual algorithm that identifies the critical feature areas.

As discussed above, semiconductor manufacturing involves imaging target patterns (e.g., desired circuit such as DRAM) on a substrate using a mask comprising a mask pattern. The mask pattern includes main features corresponding to the target patterns and assist features that are designed to cause the printed patterns to match as closely as possible to the target patterns. Such assist features are not desired to be printed on the substrate. As such, geometry of the assist feature is designed small enough to be not printed for various focus-exposure conditions used during the semiconductor manufacturing.

Existing technology employs methods to determine whether the assist features (e.g., SRAFs) of the mask pattern may print on a substrate. The existing technology may be divided into two parts—metrology technology and lithography technology that are typically used together in semiconductor manufacturing. For example, data related to printed patterns on the substrate may be collected using a metrology tool. The metrology data may be further used by one or more model to tune the lithography apparatus or related processes to improve accuracy of the printed patterns with respect to the target patterns.

On the metrology side, the metrology tool may capture an image of a printed substrate. From the image, a contour extraction algorithms can extract contours of features printed on the substrate. The extracted contours can be compared with the target patterns to determine if assist features e.g. SRAFs are printed. In an embodiment, user inputs may be used to identify contours from the images captured by the metrology tool.

On lithography side, an aerial image (AI) intensity based model may be employed to predict a probability that the assist features will be printed on the substrate. The probability values can be further used e.g., in a cost function employed in an optical proximity correction (OPC) process. The cost function guides the OPC process to modify shapes and sizes of assist features or main features so that the assist features are less likely to be printed on the substrate. For example, the cost function can be a function of AI intensity and assist feature's printing probability. In another application related to lithography, lithographic manufacturability check (LMC) may find extra contours (e.g., SRAFs) by comparing with a target pattern.

The existing technology faces several challenges. For example, on metrology side, a contour extraction based on noisy SEM images could generate incorrect contours for high variation region of printed patterns on the substrate. Since, contour extraction may involve certain thresholding e.g., to identify edges of a feature or filtering out noise, it may introduce random truncation error due to the noise in raw SEM images. On lithography side, errors may be introduced from calibrated model (e.g., calibrated based on the metrology data) because even after calibration a model residual error remains.

According to the present disclosure, there is provided method to determine a probability (also referred as a likelihood) that an assist feature may be printed on the substrate based on contour-free data related to features printed on the substrate. In other words, contours are not extracted from metrology data thereby reducing inaccuracies related to the contour extraction that may be introduced into the model predictions. Some of the advantages of the method discussed herein are improved data quality and development of very high resolution model e.g., resolution up to a nanometer pixel scale. In other words, for example, model predictions can be 1,000 times more accurate in terms of predicting a location of an assist feature on the substrate. Hence, using probability values determined based on the methods herein, several lithography and metrology related application can be improved. For example, the method herein can be employed in conjunction with an OPC (e.g., via the OPC's cost function) to determine modifications to a mask pattern.

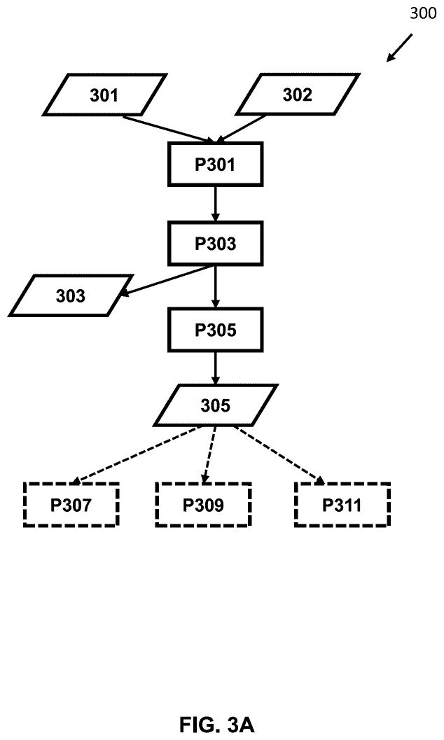

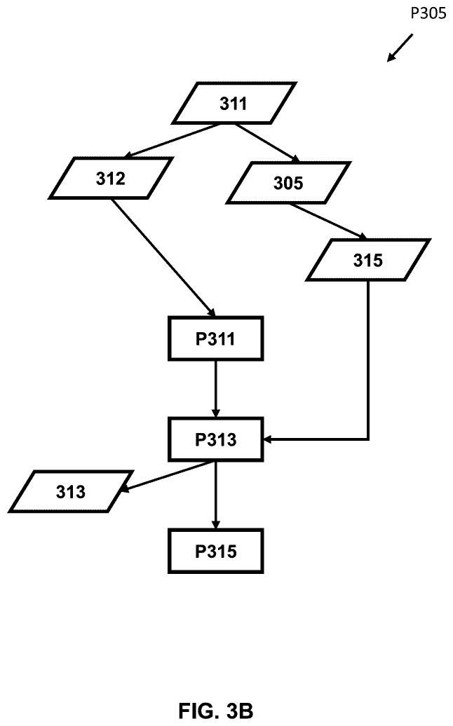

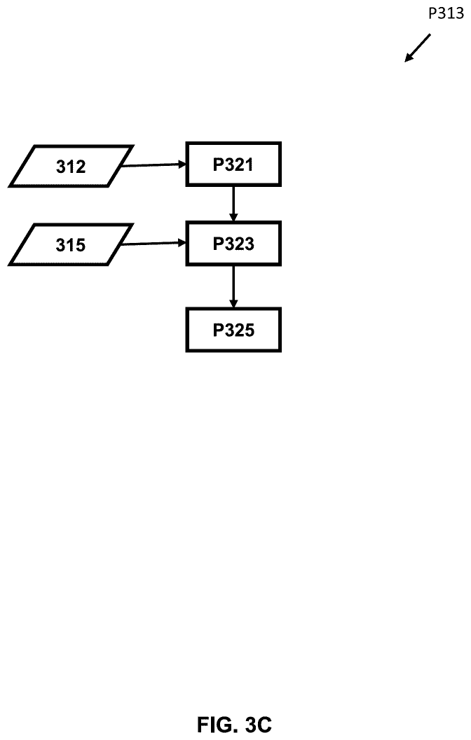

FIG. 3A is a flow chart of an exemplary process 300 for determining a likelihood that an assist feature of a mask pattern may print on a substrate according to an embodiment of the present disclosure. Unlike existing technology, the process 300 herein does not involve extraction of contours, rather uses e.g., gray scale value of accumulated metrology images of a substrate. An exemplary implementation of the method 300 includes following procedures.

Procedure P301 includes obtaining (i) a plurality of images 301 of a pattern printed on a substrate, the images having been formed using the mask pattern, and (ii) variance data 302 associated with pixels of the plurality of images 301 of the pattern. In an embodiment, optionally, average data associated with each pixel of the plurality of images 301 of the pattern may be obtained. In an embodiment, the average data can be used in addition to the variance data 302.

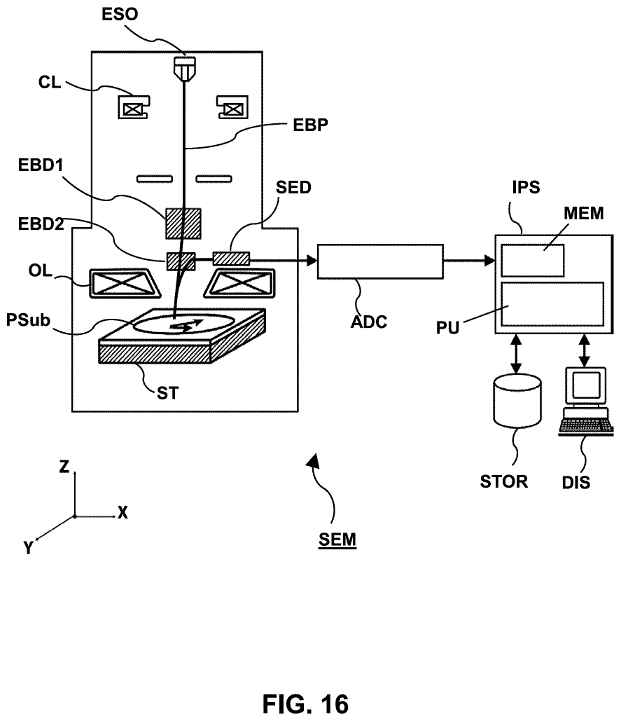

In an embodiment, the plurality of images 301 may be received, via a metrology tool. In an embodiment, the plurality of images 301 may be captured by exposing a substrate using the metrology tool the pattern printed on the substrate. In an embodiment, the metrology tool can be a scanning electron microscope (SEM) (e.g., discussed with respect to FIG. 16). In an embodiment, the images are pixelated images having a grey scale value associated with each pixel.

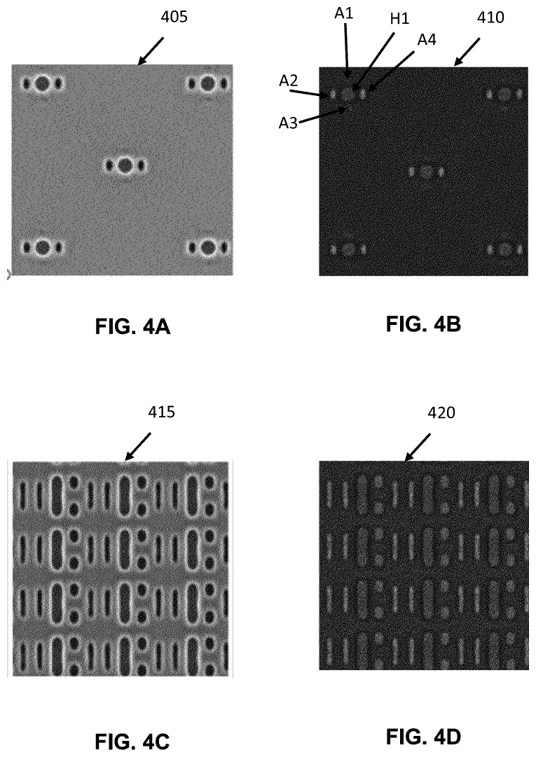

In an embodiment, the variance data 302 is represented as a pixelated image, each pixel assigned a variance value based on the grey scale values of each pixel of the plurality of images 301. In an embodiment, optionally, the average data is represented as a pixelated image, each pixel assigned an average value based on an average of grey scale values of each pixel of the plurality of images 301. According to an embodiment, examples of variance data and average data is illustrated in FIGS. 4A-4D.

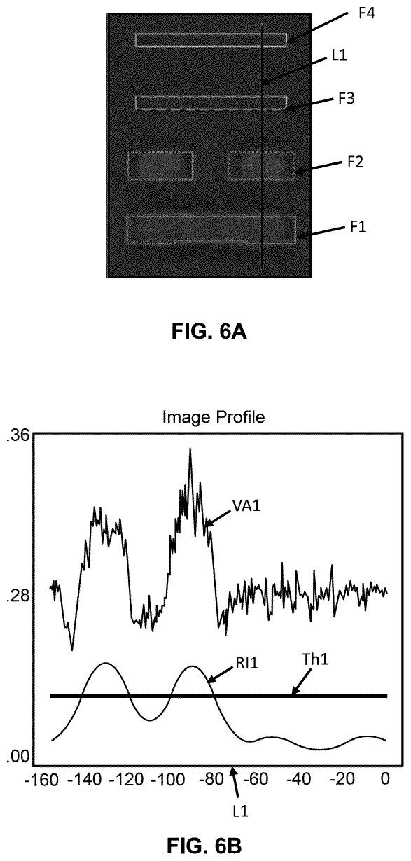

FIGS. 4B and 4D illustrate exemplary variance data 410 and 420 (examples of the variance data 302) obtained from SEM images of a first pattern and a second pattern, respectively. The first pattern comprises five contact holes and the second pattern comprises an array of lines and contact holes. In FIG. 4B, the variance data 410 for the first pattern shows variance associated with main features such as the five contact holes, and variance associated with each of four SRAFs surrounding each contact hole. For example, the variance data 410 shows variance associated with a first contact hole H1 and variance associated with each of the SRAFs A1, A2, A3, and A4, respectively. The variance data 410 is represented as an image, wherein each pixel has a grey scale value obtained from variance between the plurality of SEM images of e.g., the first pattern. In the present example, the grey scale values associated with H1 and A1-A4 indicate the amount of variance. For example, SRAFs A2 and A3 have relatively higher variance compared to SRAFs A1 and A3. This may be indicative of higher likelihood of SRAFs A2 and A3 being printed on the substrate. The process of determining a probability that an assist feature (e.g., A2 and A3) is printed is further discussed below and illustrated in exemplary FIGS. 6A-6B through 9A-9B. Similarly, variance data 420 (in FIG. 4D) represents variance associated with main features such as the lines and contact holes, and assist features that may be present around the main features.

FIGS. 4A and 4C illustrate exemplary average data 405 and 415 obtained from SEM images of a first pattern and a second pattern, respectively. The average data is represented as another image, wherein each pixel has grey scale value determined based on an average of the plurality of SEM images of e.g., the first pattern (FIG. 4A). In the present example, the average data 405 and 415 is obtained by averaging the grey scale values of the plurality of SEM images of the first pattern and the second pattern, respectively. Such average data 405 and 415 may be optionally used in different processes described herein.

Procedure P303 includes determining, based on the variance data 302, a model 303 configured to generate variance data associated with the mask pattern. In an embodiment, the model 303 can be determined using the average data in addition to the variance data 302. Accordingly, for example, the model 303 can generate variance data as well as average data for an input pattern. In an embodiment, the model 303 can receive a mask image (MI), a resist image (RI), an etch image (EI) or other images associated with a lithography or metrology process, as input. In an embodiment, the MI, RI, or EI can be obtained from a metrology tool e.g., RI can be captured after imaging a pattern in a resist on the substrate, and EI can be captured after an etch process performed the imaged pattern of the substrate. In an embodiment, images MI, RI, or EI can be obtained via simulating models (e.g., a resist model or an etch model) related to the lithography process (e.g., as discussed in FIG. 2).

In an embodiment, the model 303 is at least one of: a convolutional neural network (CNN) comprising weights and biases as model parameters, a linear model comprising a combination of linear terms associated coefficients, the coefficients being the model parameters, and a polynomial model comprising a combination of polynomial terms associated coefficients, the coefficients being the model parameters.

In an embodiment, the determining of the model 303 includes inputting (i) an aerial image or a mask image associated with the mask pattern, and (ii) the variance data 302 associated with the mask pattern to the model 303; executing the model 303 using initial values of model parameters to generate initial variance data 302; determining a difference between the initial variance data and the inputted variance data 302; and adjusting, based on the difference, the initial values of the model parameters to cause the model 303 to generate variance data that is within a specified threshold of the inputted variance data 302. In an embodiment, the aerial image or the mask image can be obtained, for example, simulation (e.g., FIG. 2) or SEM tool.

In an embodiment, the determining of the model 303 is an iterative process. In each iteration, the executing step, the determining of the difference step, and the adjusting steps can be repeated until the model-generated variance data is within the specified threshold (e.g., 0 to 5%) of the inputted variance data 302. As such, the model-generated variance data will closely match the inputted variance data 302. In an embodiment, the adjusting of the initial values of the model parameters is based on a gradient of the difference between the outputted variance map and the inputted variance, the gradient guiding the values of the model parameters toward reducing or minimizing the difference. Once the model 303 is determined, the model 303 can be used to generate variance data for any input image.

Procedure P305 includes determining, based on model-generated variance data for a given mask pattern, and a resist image or an etch image associated with the given mask pattern, the likelihood 305 that an assist feature of the given mask pattern may be printed on the substrate. In an embodiment, the likelihood 305 can be applied to adjust one or more parameters related to a patterning process or a patterning apparatus to reduce the likelihood 305 that the assist feature may print on the substrate. Additional examples of how likelihood 305 can be used in various applications (e.g., OPC, source and/or mask optimization (SMO)) related to lithography are discussed later in the disclosure.

In an embodiment, FIG. 3B is an exemplary flowchart of the process P305 of the determining of the likelihood 305 that the assist feature of a given mask pattern 311 may print on the substrate. In an embodiment, the process P305 includes following procedures. Procedure P311 includes obtaining the resist image 312 associated with the given mask pattern 311. For example, the resist image 312 can be obtained via a patterning process simulation (e.g., FIG. 2) or a metrology tool (e.g., SEM). Procedure P313 includes establishing a correlation 313 between the model-generated variance data 315 and the resist image 312. Procedure P315 includes identifying, based on the correlation 313, a region of the mask pattern or a target layout corresponding to the mask pattern that have a relatively higher likelihood of the assist feature being printed on the substrate.

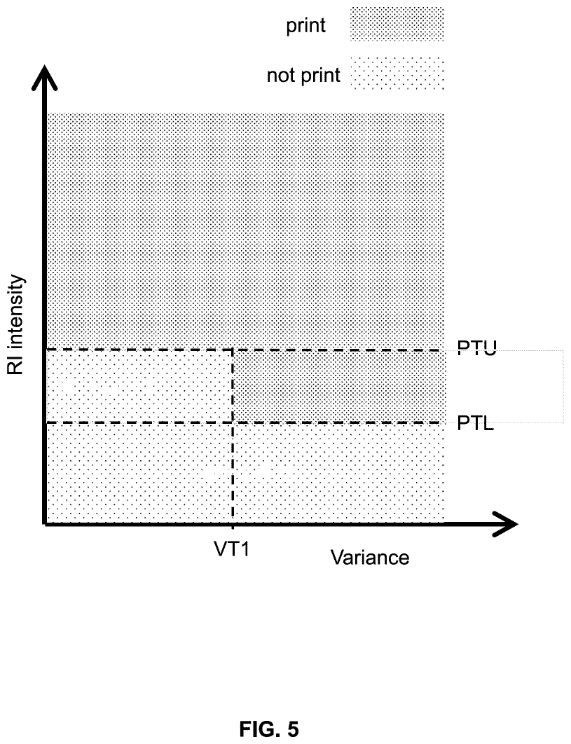

In an embodiment, FIG. 3C is an exemplary flowchart of the process P313 for the establishing of the correlation 313 between the model-generated variance data 315 and the resist image 312. The process P313 includes following procedures. Procedure P321 includes identifying, from the resist image 312, intensity values along a selected line on the resist image 312. Procedure P323 includes identifying, from the model-generated variance data 315, variance values corresponding to the selected line. Procedure P325 includes correlating the identified variance values with the identified intensity values of the resist image 312 along the selected line on the resist image 312. FIGS. 5, and 6A-9B further illustrate how the correlation between the variance data and the resist image can be used to determine regions of resist image having higher likelihood that assist feature may print on the substrate.

In an embodiment, the procedure P323 of identifying the region with relatively higher likelihood of the assist feature being printed on the substrate includes: determining, for one or more regions of the resist image 312, whether the intensity values breach a printing threshold associated with printing of a feature within a resist layer on the substrate; determining, based on the correlation 313, whether the variance values corresponding to the one or more regions breach a specified variance threshold range; responsive to the breaching of the specified variance threshold range, assigning a relatively higher probability of printing to portions of the one or more regions; responsive to the breaching of the specified variance threshold range and not breaching of the printing threshold, assigning a relatively lower probability to portions of printing to the one or more regions; responsive to not breaching of the specified variance threshold range and not breaching of the printing threshold, assigning a zero probability to portions of printing to the one or more regions; and identifying the region from the one or more regions having greater than zero probability of printing, the region being surrounding a main pattern of the mask pattern. FIGS. 5, and 6A-9B further illustrate how the correlation between the variance data and the resist image can be used to determine regions of resist image having higher likelihood that assist feature may print on the substrate.

In an embodiment, the printing threshold refers to an upper threshold value indicative of printing of a feature within the resist layer, and a lower threshold value indicative of not printing of the feature in the resist layer. For example, in FIG. 5, an upper threshold value PTU indicates a resist intensity above which a feature prints with more than 90% certainty. A lower threshold value PTL indicates a resist intensity value below which a feature does prints in the resist layer. In an embodiment, the printing threshold may depend on the focus-exposure conditions, the type of resist, critical dimension of a feature to be imaged on the resist, or other resist or lithography related characteristics.

In an embodiment, values within the specified variance threshold range are indicative of not printing of a feature, and the values outside the specified variance threshold range are indicative of printing of the feature. For example, in FIG. 5, a variance threshold range may be a variance value above VT1. Assuming for an assist feature, the variance is above VT1 and the resist intensity is between printing threshold PTL and PTU, then it may be determined the assist feature may be printed on the substrate. In other words, based on the variance data, it may be determined that an assist feature has a higher probability of printing even though the resist intensity may be not be indicative of printing of the assist feature. It can be understood that the present disclosure is not limited to a constant threshold value of the variance and the present examples do not limit the scope of the present disclosure. In an embodiment, the variance threshold may be specified as a function. In an embodiment, the variance threshold may also depend on the resist type, dose-focus conditions, and process conditions related to the patterning process.

FIGS. 6A-6B, 7A-7B, 8A-8B, and 9A-9B illustrates how variance data associated with resist images can be used in conjunction with the resist image or the etch image intensity values to determine printing of an assist feature on the substrate. FIGS. 6A, 7A, 8A, and 9A show exemplary images of resist pattern imaged on the substrate. FIGS. 6B, 7B, 8B, and 9B show exemplary variance data (e.g., VA1, VA2, VA3, and VA3) and resist image intensity data (e.g., RI1, RI2, RI3 and RI4) along a selected line L1 in each of the resist images of FIGS. 6A, 7A, 8A, and 9A, respectively. In an embodiment, raw SEM images, simulated images, or averaged SEM images (e.g., a unit cell averaging may be performed on raw image data to generate average SEM images) of the resist pattern or the etch pattern may be used for determining the likelihood of printing of a feature. It can be understood that the present embodiment is not limited to raw SEM images or averaged SEM images and does not limit the scope of the present disclosure.

In FIG. 6A, the resist image of the substrate includes features F1, F2, F3, and F4. The dotted outline (drawn for reference) around the features F1-F4 correspond to mask features such as main features and assist features. For example, features F1 and F2 correspond to main features, and features F3 and F4 correspond to assist features. An example line L1 is drawn on the resist image that passes through the features F1-F4. Along the line L1, intensity data (e.g., RI1) is extracted from the resist image. The resist image intensity data RI1 is plotted in FIG. 6B for visualization. In an embodiment, variance data may be generated via the model (e.g., the model 303) using a mask image (used to generate the resist image) as input to the model. From the model-generated variance data, variance data VA1 associated with the line L1 can be extracted. The variance data VA1 is plotted above the resist image intensity data RI1 for visualization.

Referring to FIG. 6B, the resist image intensity data RI1 is represented as a curved profile. Along the line L1, viewing from left to right, the resist intensity profile RI1 shows two peaks corresponding to the features F1 and F2 (e.g., main features), and the two relatively smaller or narrower peaks correspond to the features F3 and F3 (e.g., assisted features). In the present example, the two peaks corresponding to features F1 and F2 are above a printing threshold Th1. This indicates the features F1 and F2 will be printed on the substrate. On the other hand, the smaller peaks corresponding to features F3 and F4 are relatively further below the printing threshold Th1. This indicates that the features F3 and F4 will not be printed on the substrate. In an embodiment, the printing threshold Th1 corresponds to an upper limit (e.g., PTU in FIG. 5).

In FIG. 6B, the variance data VA1 along the line L1, viewing from left to right, also shows two peaks corresponding to locations of the peaks in the resist profile RI1, and relatively flat profile towards the right corresponding to smaller peaks in the resist profile RI1. In an embodiment, a relatively high variance in the variance data VA1 indicate that a feature may be printed on the substrate, while a relative low variance in the variance data VA1 indicates that a feature may not be printed on the substrate. For example, based on VA1 data, the first two peak (i.e., relatively high variance) correspond to the features F1 and F2, and the relative low variance correspond to the features F3 and F4. In an embodiment, the relatively high and low variance may be determined based on a variance threshold value (e.g., a specified threshold such as VT1 of FIG. 5) or a range of variance threshold. Thus, resist image intensity data RI1 and variance data VA1 can be correlated and used to determine a probability that a feature may print on the substrate.

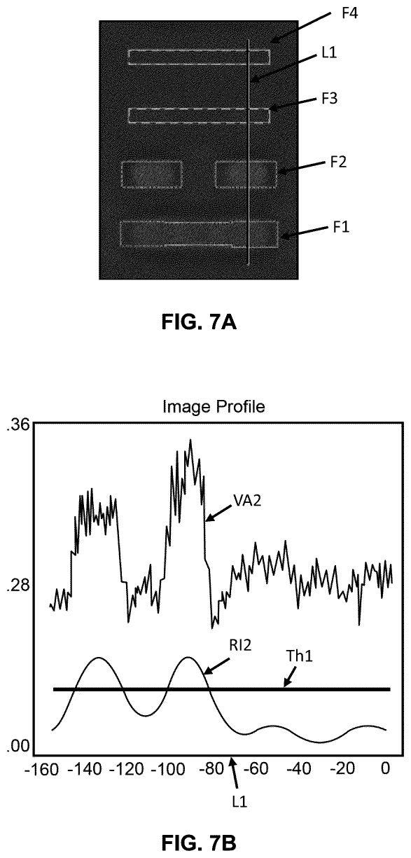

FIGS. 7A and 7B is another example where the resist image is obtained at different process conditions. FIG. 7B shows similar behavior as FIG. 6B discussed above. Similar to the discussion above, the resist image intensity data RI2 and the variance data VA2 show two peaks on the left side and relative flat portions on the right side. The two peaks on the left side of the resist image intensity data RI2 and corresponding peaks in variance data VA2 indicate that the features F1 and F2 may be printed. Also, the relatively flat portions in RI2 and VA2 on the right side indicate that features F3 and F4 will not be printed.

In an embodiment, locations on the resist image where the resist image intensity data (or profile) is above the threshold Th1, the probability of printing is assigned a value of 1 or 100%, which indicates there is substantially 100% chance that the feature may be printed on the substrate. On the other hand, locations on the resist image where the resist image intensity data is substantially below the threshold Th1 is assigned a probability of a value of 0 or 0%, which indicates there is substantially 0% chance that the feature may be printed on the substrate.

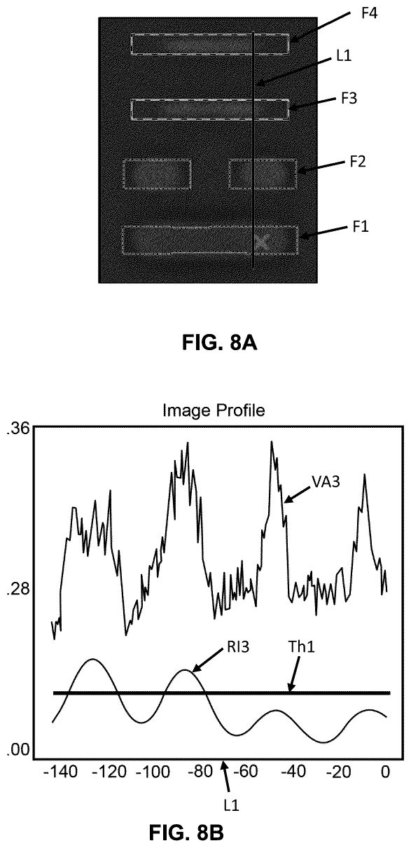

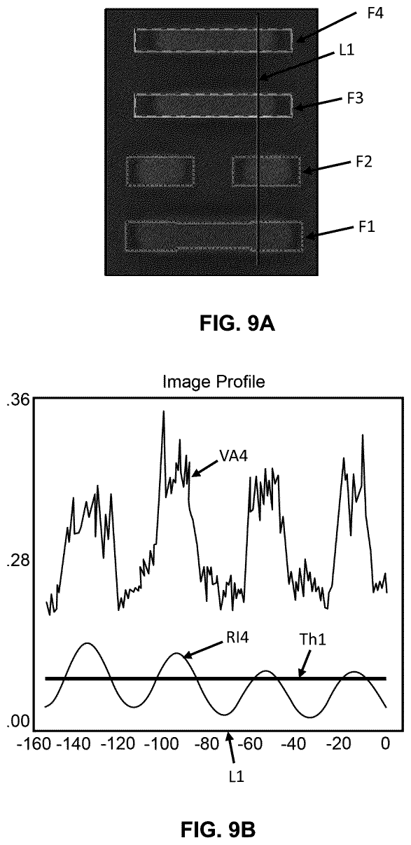

However, if a location has the resist image intensity data that is close to the threshold Th1 or within a specified range of the threshold Th1 (e.g., corresponding to PTL and PTU of FIG. 5), then the probability that a feature (e.g., an assist feature) may print at that location can be any value between 0 and 1 (or 0% and 100%). In this case, variance data VA1 can be referred to determine a probability that a feature (e.g., an assist feature) may print on the substrate. FIGS. 8A-9B further discuss an example where the resist profile data is support by the variance data to determine the probability that a feature (e.g., an assist feature) may print on the substrate.

FIGS. 8A-8B and 9A-9B show examples of resist images obtained at different process conditions. As discussed above, along the line L1, intensity data can be extracted from the resist images and variance data can be extracted from model-generated variance data. In FIGS. 8B and 9B, along the line L1, the variance in VA3 and VA4 is relatively high and the resist image intensity profile RI3 and RI4 are relatively close to the threshold Th1. For example, in FIG. 8B, the resist image intensity profile RI3 shows four peaks. The two peaks on the left side are substantially above the threshold Th1. These two peaks correspond to the feature F1 and F2 (in FIG. 8A). However, two peaks in RI3 on the right side are close to, but below, the threshold Th1. These two peaks in RI3 correspond to the features F3 and F4 (in FIG. 8A). Now, referring to the variance data VA3, there are four peaks of approximately equal amplitude. The first two peaks (on the left) correspond to the peaks in RI3 both indicating that the probability that the features F1 and F2 may be printed is 100%. On the other hand, the two peak in RI3 that are below the threshold Th1 may indicate that the features F3 and F4 may not print. However, corresponding peaks in the variance data VA3 indicate that the features F3 and F4 have relatively high probability of being printed on the substrate, since the variance is relatively high.

Similarly, referring to FIG. 9B, the resist image intensity data RI4 and the variance data VA4 indicate RI4 has peaks close to the threshold Th1. Corresponding to the peaks in RI4, the variance data VA4 also has peaks indicative that the features F1-F4 (in FIG. 9A) have relatively high probability of getting printed on the substrate.

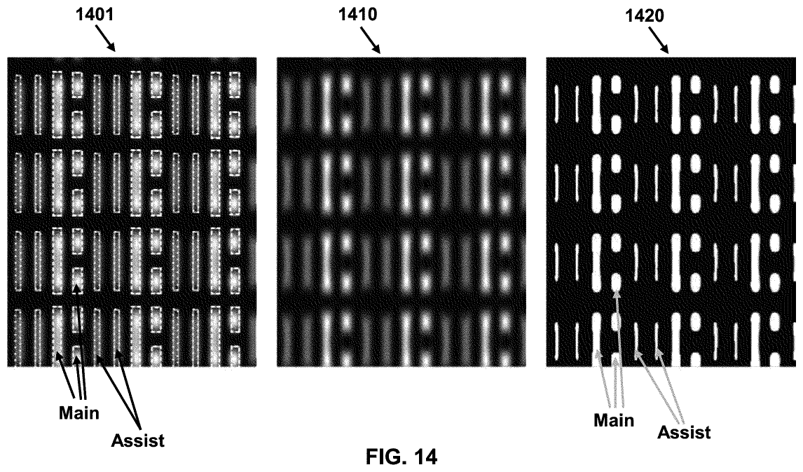

In an embodiment, above examples in FIGS. 6A-9B illustrate the variance data (or variance image) may be used as a guiding map in conjunction with a resist image or an etch image to determine a probability that a feature (e.g., an assist feature) may print on the substrate. Hence, for a given mask pattern locations or assist features having relatively high probability of getting printed on the substrate can be identified. Further, the identified assist features can be modified so that they do not print on the substrate. For example, the variance data and the resist image intensity data can be used to determine locations on a mask pattern during an optical proximity correction (OPC) process. Depending on the probability of printing of an assist feature, the identified location can be penalized more or less. The penalty function may be implemented via a cost function of the OPC process, discussed herein. For example, locations with higher variance indicate a high probability of printing, hence the OPC process may penalize the locations or features (e.g., SRAFs) relatively more than other locations so that the OPCed features are adjusted to minimize the probability of printing of the features (e.g., SRAFs). An exemplary OPC process and example cost function are discussed with respect to FIGS. 14-17.

In an embodiment, a resist model (e.g., in FIG. 2) or an etch model used to generate the resist image or an etch image, respectively, is trained based on main features that are printed with 100% probability. The resist model may not be calibrated on data related to features that may not print on the substrate or have relatively low probability of printing. As such, the present disclosure can be used in combined with the existing lithographic simulation processes to make better predictions of probability that a feature may print and improve the yield of the patterning process. Additional examples of the present process 300 are further discussed below.

Referring back to FIG. 3A, the process 300 has several applications. The process 300 can be modified to optionally include following procedures P307, P309 or P311.

In an embodiment, procedure P307 includes generating, based on the model 303 and the likelihood 305 that the assist feature may print on the substrate, optical proximity correction (OPC) data to adjust one or more main features, or one or more assist features of the mask pattern. In an embodiment, the generating of the OPC data includes adjusting, via the OPC simulation process (e.g., FIGS. 14-17) associated with the patterning process, a shape and/or size of the one or more main features, or the one or more assist features of the mask pattern. The adjusted shape and/or size reduces the likelihood 305 that an assist feature may print on the substrate. In an embodiment, the OPC process may remove the one or more assist features of the mask pattern.

In an embodiment, procedure P309 includes determining, based on the model 303 and the likelihood 305 that the assist feature may print on the substrate, a source and/or a mask pattern to reduce the likelihood 305 that an assist feature may print on the substrate. The determining of the source and/or the mask pattern includes adjusting, via a source mask optimization (SMO) process, source parameters and/or mask parameters to cause reduction in the likelihood 305 that the assist feature of the mask pattern may print on the substrate.

In an embodiment, procedure P311 includes adjusting, based on the model 303 and the likelihood 305 that the assist feature may print, one or more parameters of a patterning process used for patterning the substrate. The adjusting of the one or more parameters of the patterning process includes determining, using a mask image or an aerial image of a pattern being printed on the substrate as input the model 303, a likelihood 305 that an assist feature may print on the substrate; and adjusting the one or more parameters of the patterning process to reduce the likelihood 305 that the assist feature may print on the substrate. In an embodiment, the one or more parameters includes, but not limited to, dose of a scanner, focus of the scanner, and/or a substrate table height.

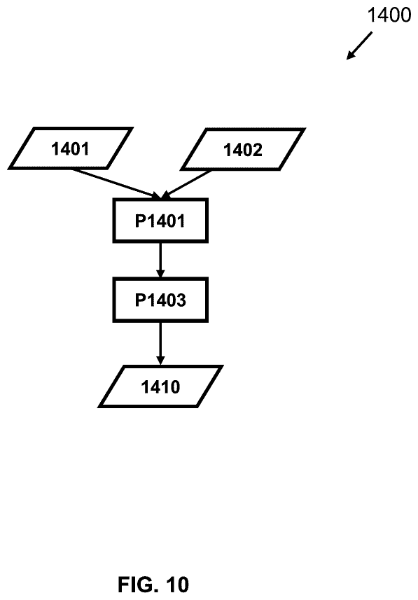

FIG. 10 is a flow chart of a process 1400 for generating a model associated with a mask pattern to determine variance data associated with the mask pattern. As mentioned earlier, the process does not involve extraction of contours, rather uses e.g., gray scale value of accumulated metrology images of a substrate. An example implementation of the process 1400 includes following procedures.

Procedure P1401 includes obtaining (i) a plurality of images 1401 of a pattern printed on a substrate using the mask pattern, and (ii) variance data 1402 associated with each pixel of the plurality of images 1401 of the pattern. In an embodiment, optionally, average data associated with each pixel of the plurality of images 1401 of the pattern may be obtained. In an embodiment, the average data can be used in conjunction with the variance data 1402. In an embodiment, the plurality of images 1401 are SEM images obtained via a SEM tool. In an embodiment, optionally, average data associated with each pixel of the plurality of images 1401 of the pattern may be determined and used as training data for generating the model.

In an embodiment, the variance data 1402 is represented as a pixelated image, each pixel assigned a variance value of the grey scale values of each pixel of the plurality of images 1401. For example, variance data represented as images in FIGS. 4B and 4D. Likewise, optionally, the average data is represented as a pixelated image, each pixel assigned an average value of grey scale values of each pixel of the plurality of images.

Procedure P1403 includes generating, based on the variance data 1402, a model 1410 configured to predict variance data associated with the mask pattern, the variance data being used to determine a likelihood that an assist feature of the mask pattern may print on the substrate. In an embodiment, the model 1410 is at least one of: a convolutional neural network comprising weights and biases as model parameters, a linear model comprising a combination of linear terms associated coefficients, the coefficients being the model parameters, and a polynomial model comprising a combination of polynomial terms associated coefficients, the coefficients being the model parameters.

In an embodiment, the generating of the model 1410 includes inputting (i) an aerial image or a mask image associated with the mask pattern, and (ii) the variance data 1402 associated with the mask pattern to the model 1410; executing the model 1410 using initial values of model parameters to generate initial variance data; determining a difference between the initial variance data and the inputted variance data 1402; and adjusting, based on the difference, the initial values of the model parameters to cause the model 1410 to generate the variance data that is within a specified threshold of the inputted variance data 1402.

In an embodiment, the generating of the model 1410 is an iterative process, wherein the adjusting of the values of the model parameters is performed until the model generated variance data is within the specified threshold of the inputted variance data 1402.

In an embodiment, the adjusting of the initial values of the model parameters is based on a gradient of the difference between the outputted variance map and the inputted variance, the gradient guiding the values of the model parameters toward reducing or minimizing the difference.

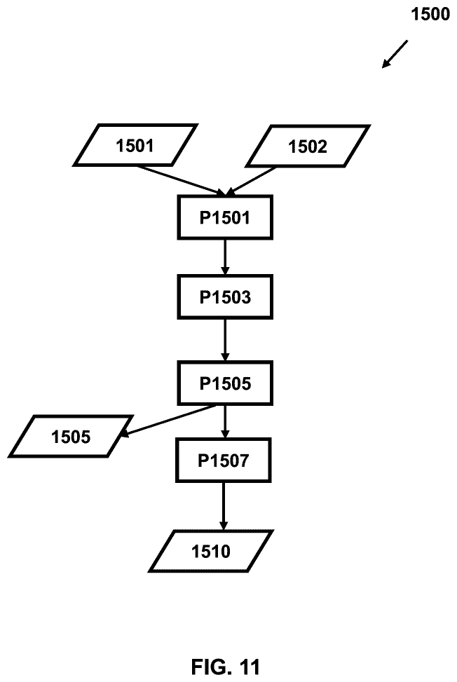

FIG. 11 is a flow chart of a process 1500 for generating optical proximity correction data for a mask pattern. An example implementation of the method 1500 includes following procedures.

Procedure P1501 includes obtaining (i) a mask image 1501 or an aerial image 1502 associated with the mask pattern, and (ii) a resist image or an etch image associated with the mask pattern. In an embodiment, the obtaining of the mask image 1501 or the aerial image 1502 includes simulating one or more process models using the mask pattern to generate the mask image 1501, or the aerial image 1502.

Procedure P1503 includes executing a model (e.g., 303 or 1410) configured to predict variance data 1505 associated with the mask pattern. The model (e.g., 303 or 1410) is configured to use the mask image 1501 or the aerial image 1502 as input and output the variance data 1505 associated with the mask pattern. Procedure P1505 includes determining, based on the model-generated variance data 1505, and the resist image 1501 or the etch image 1502, a likelihood that an assist feature of the mask pattern may print on a substrate.

Procedure P1507 includes generating, based on the likelihood that the assist feature may print, the optical proximity correction (OPC) data 1510 for modifying one or more main features, or one or more assist features of the mask pattern. In an embodiment, the generating of the OPC data 1510 includes adjusting, via an OPC simulation process, a shape and/or size of the one or more main features, or the one or more assist features of the mask pattern. The adjusted shape and/or size reduces the likelihood that an assist feature may print. In an embodiment, OPC data 1510 involves removing, via the OPC simulation process, the one or more assist features of the mask pattern. In an embodiment, the OPC data can be applied via a patterning device modification tool to modify the mask pattern on a mask.

As discussed earlier, semiconductor manufacturing involves imaging a mask pattern on a substrate to form a desired electrical circuit of a chip. The mask pattern includes assist features (e.g., SRAFs) to form the printed patterns on the substrate that closely match a design pattern. In an embodiment, the printed patterns are inspected to determine whether any assist features are printed on the substrate. Such printing of the assist feature is not desired. In an embodiment, a SEM image of the printed pattern on the substrate is inspected to determine a quality of printing of the pattern based on whether assist features are printed or not. The SEM images and data (e.g., pixel intensities, feature information, etc.) within the SEM images can be used to train one or more process models to improve the yield of the patterning process.

However, typically SEM images that include assist features (e.g., SRAFs) may be of poor image quality (e.g., blurry, or noisy). Such SEM image can make identifying assist features challenging due to e.g., blur or noise around the assist feature locations. When such SEM images are used for training one or more process models (e.g., configured to determine a printed pattern on the substrate or to determine whether an SRAF is printed), the models may not produce accurate results. For example, the process model can be a resist model that produces a resist image. The resist model is a simplified model used to determine a resist image that may be formed the substrate. Based on the resist image, a patterning process may be tuned. The tuning can be adjusting, for example, dose, focus, or resist parameters to cause a desired pattern on the substrate. As such, the resist model should be configured to determine if e.g., SRAF may be printed, so that tuning can be performed more accurately to remove the SRAF features.

In the present disclosure, a printability map (also referred as a probability map) is generated that determines a probability that assist features may print on the substrate. The printability map can be generated for any mask pattern desired to be printed on the substrate. The printability map can serve as a guide to determine one or more parameters of the patterning process to prevent the assist features from printing on the substrate. The printability map can be considered as a two-dimensional (2D) map that is different from a one dimensional (1D) gauge data (e.g., CD). In an embodiment, the printability map comprises SRAF printing probability values, which are values between 0% and 100% (or real number between 0 to 1) associated with each pixel in a 2D plane of the image.

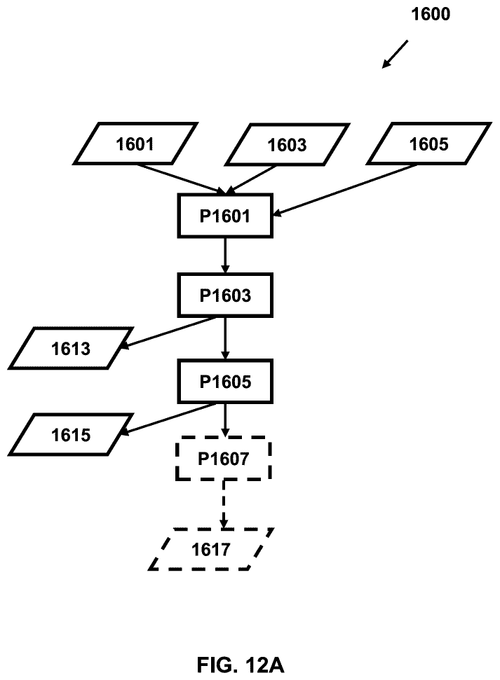

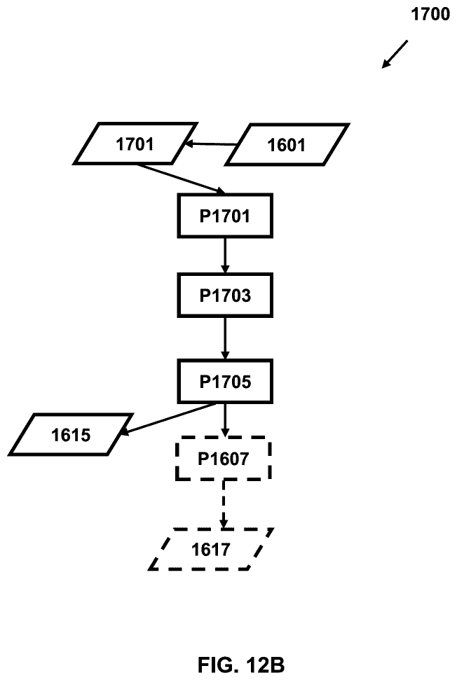

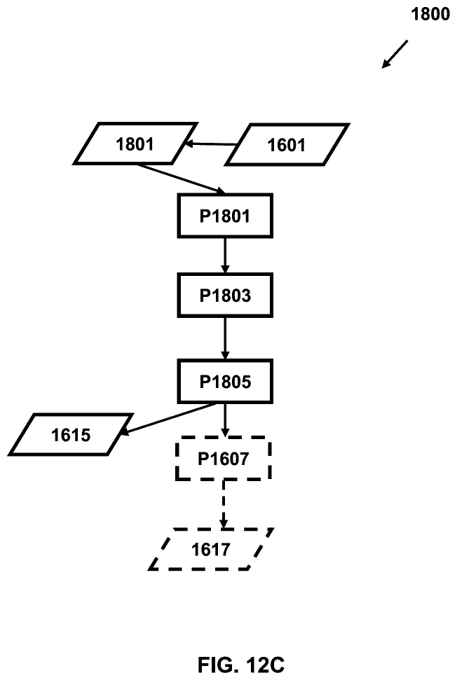

FIG. 12 is an exemplary flow chart of a method 1600 for generating a printability map associated with a mask pattern. In an embodiment, for example, the method 1600 includes steps to acquire patterned substrate images including SRAF data for a mask pattern. For example, a plurality of SEM images from different substrate dies for the same mask pattern can be acquired via a SEM tool. These raw SEM images may be aligned using e.g., a die-to-die alignment tool. For each aligned image, an image segmentation can performed. Based on the segmented images, refined images such as a binary images can be generated. The binarized images provides information on whether assist features may be printed or not printed for each pixel. These binarized images are stacked to generate a probability map, where each pixel in the probability map is a printing probability. The printing probability is determined, for example, by dividing a binary image number by a total number of binary maps.

In an embodiment, the accuracy of the printability map depends on accuracy of the image segmentation of SEM images. Compared to existing contour extraction methods, e.g. ridge detection, an issue is, the individual SEM image used for image segmentation here are much more noisy than an averaged image used for the ridge detection. Also, compared to a general image segmentation method, the present method 1600 provides a different marker-based image segmentation, as disused herein. The method 1600 is implemented as example processes P1601, P1603, and P1605, discussed in detail below.

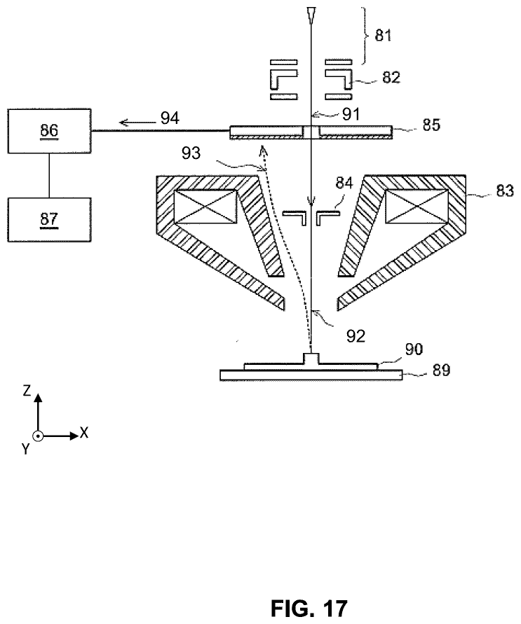

Process P1601 includes obtaining (i) a plurality of images 1601 of a patterned substrate, (ii) a plurality of refined images 1603 based on the plurality of images 1601, and (iii) a simulated refined image 1605 based on the mask pattern. In an embodiment, the obtaining of the plurality of images 1601 includes receiving, via a metrology tool, the plurality of images 1601 of the pattern printed on the substrate. In an embodiment, the obtaining of the plurality of images 1601 includes capturing, via the metrology tool, the plurality of images 1601 of the pattern printed on the substrate. As discussed herein, the plurality of images 1601 of a patterned substrate can be obtained via a scanning electron microscope (SEM) (see FIGS. 16 and 17). Accordingly, each image of the plurality of images 1601 is a SEM image.

In an embodiment, one or more refined images of the plurality of refined images 1603 are one or more binary images. For example, a portion of a feature (e.g., main feature or assist feature) is assigned a value 1 and pixels surrounding the feature have a value 0. The simulated refined image 1605 can be also be another binary image, where each pixel has a value of either 0 or 1. For example, a portion of a feature (e.g., main feature or assist feature) has a value 1 and pixels of surrounding area of the feature have a value 0.

In an embodiment, the obtaining of the plurality of refined images 1603 includes denoising each of the plurality of images 1601. For example, denoising raw SEM images of a pattern on the substrate. In an embodiment, each of the denoised plurality of images 1601 is further converted, via an adaptive thresholding algorithm, a refined image. The adaptive thresholding algorithm can be any algorithm than adaptively finding an optimal threshold to distinguish between printing and not printing areas within an image (e.g., SEM image). In an embodiment, the adaptive thresholding algorithm is an Otsu thresholding algorithm configured to receive the plurality of images 1601 or the denoised plurality of images 1601 and the markers within each of the plurality of images 1601 as input and output a refined image.

In an embodiment, the denoising of the plurality of images 1601 includes applying a first median filter and a Gaussian filter to each of the plurality of images 1601 such that a ridge edge accuracy associated with each of the plurality of images 1601 is maintained, the first median filter characterized by a first kernel size; applying a second median filter to enhance image contrast of each of the plurality of images 1601, the image contrast being between printing area and not printing area, the second median filter characterized by a second kernel size, the second kernel size being greater than the first kernel size; and applying a third filter to further decrease noise in the plurality of images 1601, the third filter characterized by a third kernel size.

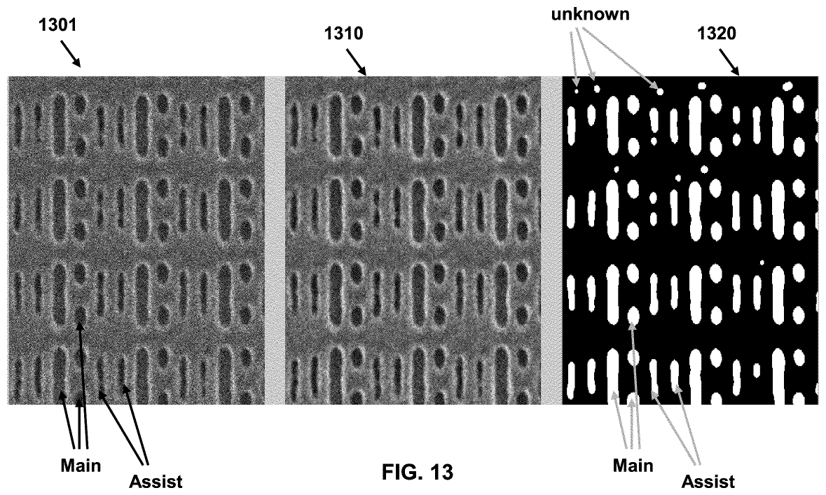

FIG. 13 illustrate an example of generating of a refined image 1320 from a raw SEM image 1301 of a patterned substrate. The raw SEM image 1302 is noisy which makes it difficult to identify an contour or outline of features within the image based on pixel intensity. In an embodiment, one or more filters can be applied to reduce or remove the noise within the raw image 1302. In an embodiment, the denoising of the raw image 1301 can be performed applying a first median filter and a Gaussian filter to make the raw image 1301 relatively smoother. For example, the first median filter can be a non-linear noise filter characterized by a first kernel size (e.g., 3×3). The Gaussian filter can be a blur filter configured to reduce the blur of the raw image 1301 while maintaining ridges within the image. For example, ridges within the image are characterized by local maxima (e.g., maximum intensity) around features of interest (e.g., holes, lines, etc.) in the raw image 1301. After applying the first filter and the Gaussian filter, the denoised image (not illustrated) is obtained.

Further, a second median filter is applied to the denoised image to enhance the image contrast. The image contrast is a difference in pixel intensities between printing area and not printing area of the substrate. For example, image contrast around main features and assist features within the denoised image is enhanced. The second median filter can be characterized by a second kernel size, which is greater than the first kernel size. Applying the second filter, a denoised image 1310 is obtained. The denoised image 1310 has relatively less noise, sharper edges, and better contrast around the features compared to the raw image 1301. Further, a third filter can be applied to the denoised image 1310 to further reduce the noise. The third filter can be referred as a minimum filter having a kernel size similar to or smaller than the first filter. An adaptive thresholding algorithm is then applied to the denoised image 1301 to generate the refined image 1320. The refined image 1320 is used to guide an image segmentation process as discussed herein. In an embodiment, the refined image 1320 can be a binarized image. In an embodiment, the adaptive threshold algorithm can be Otsu algorithm that coverts the denoised image 1310 into a binarized image 1320. In the adaptive thresholding algorithm, a threshold value is calculated for portions e.g., based on features (e.g., main feature and assist features) of the denoised image. As such, the adaptive thresholding is different from a simple threshold, wherein a single threshold value is applied globally to the image. As a result of the adaptive thresholding, a more refined image 1302 that highlights features within the raw image 1301 can be obtained. In an embodiment, the highlighted features (e.g., white regions in 1320) correspond to the main features (e.g., lines and holes), assist features around the main features.

Additionally, some unknown features may be present in the refined image 1320. These unknown features may not be readily visible in the raw image 1301, the denoised image 1302, or even the mask pattern that is used to generate the patterned substrate. Such unknown features may not be desired and may be removed by comparing with a simulated refined image (see 1420 in FIG. 14). In an embodiment, the unknown features may be remove because they are not intended main or SRAF features, rather they may originate from SEM noises, or erroneous signals resulting from the process of generating the refined images The simulated refined image (see 1420 in FIG. 14) serves as a guide to identify features associated with the mask pattern and ignore the unknown features. The process of obtaining the simulated refined image and further comparing with the refined image (e.g., 1320) is discussed below.

Referring back to FIG. 12, at the process P1601, the obtaining of the simulated refined image 1605 includes executing one or more process models of the patterning process using the mask pattern and process conditions corresponding to each of the plurality of images 1601 to generate the simulated image of a pattern that will be printed on a substrate; and applying a selected threshold intensity value to the simulated image to generate the simulated refined image 1605.

FIG. 14 illustrate an example of generating of a refined simulated image 1420. In an embodiment, a simulated image 1401 is generated by executing one or more process model (e.g., as discussed in FIG. 2) using the mask pattern (not illustrated) used pattern the substrate. For example, the simulated image 1401 can be an aerial image or a resist image generated by executing the optics model or the resist model of the patterning process (e.g., as discussed in FIG. 2). In FIG. 14, the simulated image 1401 is overlaid with contours of target features and assist features for reference. A ridge magnitude image 1410 of the simulated image 1401 is shown to highlight the features within the simulated image 1401. In an embodiment, an intensity thresholding can be applied to the simulated image 1401 to generate a refined image, also referred as a simulated refined image 1420. In an embodiment, the intensity threshold value can be applied globally to the simulated image 1401. In an embodiment, an adaptive thresholding can be applied to the simulated image 1401 to generate the simulated refined image 1420. In an embodiment, the simulated refined image 1420 is a binary image as shown, where the features have a value of 1 and the surrounding of the features have a value of 0. Thus, the simulated refined image 1420 clearly identifies location of main features and assist features associated with the mask pattern.

In an embodiment, the main feature and the assist features of the simulated refined image 1420 are aligned with the respective main features and assist features of the refined image 1320 (see FIG. 13) of the raw SEM image. Thus, any unknown features in the refined image 1320 (see FIG. 13) can be ignored and image segmentation of the image can be performed accurately. The image segmentation process involves identifying the features within the image (e.g., the raw image 1301 or the denoised image 1310 of FIG. 13) based on the aligned refined images and placing markers around the features. The image segmentation process is further discussed in detail below.

Referring back to FIG. 12, process P1603 includes marking each of the plurality of images 1601 based on the plurality of the refined images, the simulated refined image 1605, and an intensity of pixels within each of the plurality of images 1601. Such marking generated a plurality of marked images 1613 corresponding to the plurality of images 1601.

In an embodiment, the marking of each of the plurality of images 1601 includes aligning a refined image of the plurality of the refined images with the simulated refined image 1605; identifying features within the refined image that correspond to features within the simulated refined image 1605; aligning an image of the plurality of image with the aligned refined image; and placing, based on the identified features, markers on the aligned image, each marker being placed at a location associated with a local minima of the intensity within the image around the identified feature.

In an embodiment, the placing of the markers includes determining a contour of an identified feature within the refined image; aligning the contour with a corresponding feature in the image of the plurality of images 1601; identifying locations of the markers around the contour in a normal direction to the contour; and generating a plurality of pair of markers. A pair of markers includes a first marker located inside a contour of the corresponding feature in the image, and a second maker located outside the contour of the corresponding feature in the image. In an embodiment, the contour of the feature in the image 1601 can also be part of the marker.

In an embodiment, the generating of the plurality of pair of markers includes determining the first marker at the local minima of the intensity of the image inside of the contour. In an embodiment, the local minima can be determined along a normal direction to the contour. Further, the second marker is determined at another local minima of the intensity of the image toward the outside of the contour and across a local maxima of the intensity of the image. In an embodiment, the second local minima or the local maxim can be determined along the normal direction to the contour. Accordingly, a marked image 1613 including the first maker and the second marker is generated corresponding to an image of the plurality of images 1601. In an embodiment, the marked image 1613 also includes contours of the features.

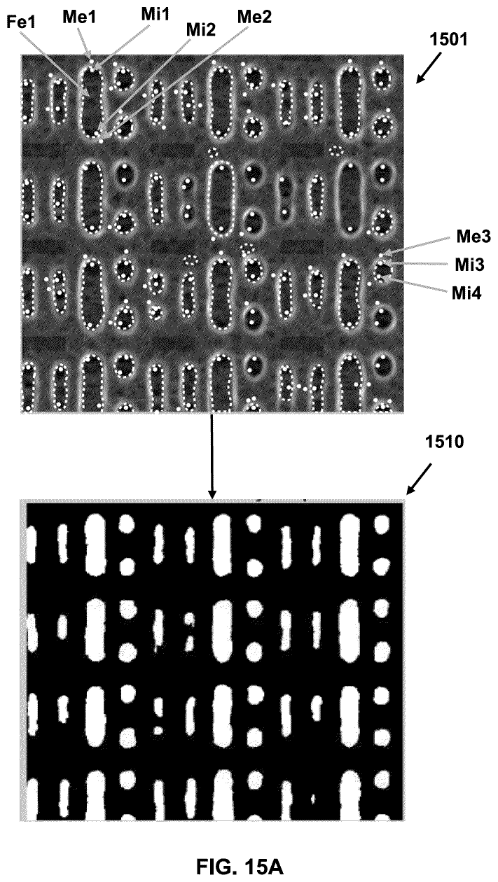

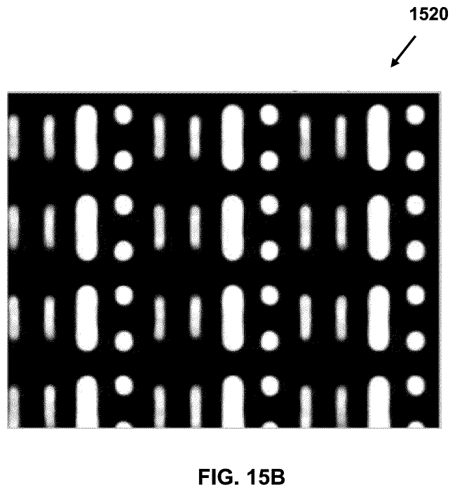

FIG. 15A illustrate an example of generating of a segmented image 1501 and another refined image 1510 corresponding to a SEM image (e.g., the raw image 1301 or the denoised image 1310). In an embodiment, the segmented image 1501 is generated by placing markers (e.g., points) within an image (e.g., the raw image 1301 or the denoised image 1310). In an embodiment, markers are indicative of information associated with specific locations within a given image (e.g., 1301 or 1310). In an embodiment, the information linked to the marker can be a location with respect to a feature of interest or a design layout, an intensity associated with the location, or other information directly available or derived therefrom.

In an embodiment, the placing of the markers includes determining a contour of an identified feature within the refined image (e.g., the refined image 1320 of FIG. 13). The contour is aligned with a contour of a corresponding feature Fe1 in a given image 1501 (e.g., the image 1301 or 1310). A normal (not shown) is drawn to the contour of the feature Fe1 of the given image 1501 (e.g., 1301 or 1310). Along the normal, locations of the markers Mi1, Me1, Mi2, and Me2 are determined. In an embodiment, the marker is a pair of markers comprising a first marker Mi1 (or Mi2) located inside the contour of the corresponding feature Fe1 in the image 1501, and a second maker Me1 (or Me2) located outside the contour of the corresponding feature Fe1 in the image 1501.

In an embodiment, a local minima of the image intensity inside of the contour of the feature Fe1 is determined. This local minima is the location of the first marker Mi1 (or Mi2). Similarly, another local minima of the intensity profile toward the outside of the contour of the feature Fe1 and across a local maxima (e.g., at the contour (dotted)) of the intensity of the image is determined. This another local minima is the location of the second marker Mei1 (or Mei2). In an embodiment, the local minima may be determined in a specified direction e.g., along a normal direction to the contour.

In an embodiment, the segmented image 1501 can be represented as a pixelated image, a matrix or other data formats that are readable by a computer readable medium, importable, and/or exportable by a program implemented on the computer readable medium. The segmented image 1501 converted to another refined image 1510 that are further used to determine the printability map as discussed below. For example, the segmented image 1501 is converted to a refined image 1510 using a watershed algorithm.

Referring back to FIG. 12, process P1605 includes generating, based on the markings, a printability map 1615 associated with the mask pattern. In an embodiment, the generating of the printability map 1615 includes inputting the marks of the plurality of images 1601 to an algorithm configured to generate a plurality of another refined images corresponding to each image of the plurality of images 1601. In an embodiment, the printability map 1615 is a spatial distribution of probability values indicating likelihood that features of the pattern will be printed on a substrate.

In an embodiment, the algorithm used for generating another refined images is a watershed algorithm configured to perform image segmentation based on the markers placed within the plurality of images 1601. In an embodiment, the watershed algorithm is configured to generate a binary image as the refined image.

In an embodiment, a model can be used for generating another refined images such as a convolutional neural network (CNN) comprising weights and biases as model parameters. The convolutional neural network is configured to generate a refined image based on the plurality of images 1601 and the markers within the plurality of images 1601. In an embodiment, such a CNN can be trained using a training data set comprising an aerial image or a resist image of a mask pattern, and reference printability maps 1615 (as ground truth). For example, the training of CNN comprises determining values of model parameters to cause the CNN to generate a printability map that closely matches the reference printability map 1615, when an aerial image or a resist image of a mask pattern is inputted to the CNN.

Furthermore, the process P1605 includes aligning the plurality of another refined images with respect to each other; and generating, based on intensity values of the aligned plurality of another refined images, the printability map 1615 for at least one of the plurality of another refined images.

In an embodiment, the generating of the printability map 1615 includes determining a probability value of each pixel of the printability map 1615 by: summing the image intensity of another refined images of the plurality of refined images 1603; and dividing the image intensity of the summed image by the total number of refined images 1603.

FIG. 15B illustrate an exemplary printability map 1520 generated from a plurality of refined images 1603 like images 1510 (discussed earlier). In an embodiment, the printability map 1520 is generated by summing image intensity of another refined images (e.g., 1510s) of the plurality of refined images; and dividing the image intensity of the summed image by the total number of refined images 1603.

In an embodiment, the method 1600 further includes process P1607 for generating values 1617 of one or more parameters of the patterning process based on the printability map 1615.

In an embodiment, the generating of the values 1617 includes inputting the printability map 1615 associated with the mask pattern to an optical proximity correction (OPC) process; determining a probability associated an assist feature of the mask pattern from the printability map 1615, the probability indicative of whether the assist feature will print on a substrate; generating, based on the probability of the assist feature, OPC data to adjust one or more main features, or one or more assist features of the mask pattern to minimize the probability that the assist feature will print on the substrate.

In an embodiment, the generating of the OPC data includes adjust, via the OPC simulation process associated with the patterning process, a shape and/or size of the one or more main features, or the one or more assist features of the mask pattern, the adjusted shape and/or size reducing the probability that an assist feature will print on the substrate; or remove, via the OPC simulation process associated with the patterning process, the one or more assist features of the mask pattern.

In an embodiment, the generating of values 1617 of the parameters of the patterning process includes determining, based on the printability map 1615, parameters associated with a source and/or a mask pattern to reduce the probability that an assist feature will print. In an embodiment, the determining of the source and/or the mask pattern includes adjusting, via a source mask optimization (SMO) process, source parameters and/or mask parameters to cause reduction in the probability that the assist feature of the mask pattern will print on the substrate.

In an embodiment, the generating values of 1617 the one or more parameters of the patterning process includes adjusting, based on the printability map 1615, one or more parameters associated with a patterning apparatus used for patterning the substrate to cause a reduction in the probability that an assist feature will print on the substrate. In an embodiment, the one or more parameters comprises: dose of a scanner, focus of the scanner, and/or a substrate table height.

In an embodiment, referring to FIG. 12B, another flow chart is provided for a method 1700 for generating a printability map associated with a mask pattern. The method 1700 includes following processes P1701, P1703, and P1705 discussed in detail below.

Process P1701 includes obtaining a plurality of refined images 1701 of a patterned substrate based on markings of a plurality of images 1601 of a patterned substrate. The markings of each image of the plurality of images 1601 are associated with an intensity of a pixel of the each image. In an embodiment, the obtaining of the plurality of refined images 1701 is similar to that discussed in method 1600. For example, the plurality of refined images 1701 are obtained by inputting the marks of the plurality of images 1601 to an algorithm configured to generate the plurality of refined images 1701 corresponding to each image of the plurality of images 1601. In an embodiment, the algorithm is a watershed algorithm configured to perform image segmentation based on the markers placed within the plurality of images 1601.

Also as discussed herein, the marking of each of the plurality of images 1601 includes aligning a binarized image of the plurality of images 1601 with a simulated refined image; identifying features within the binarized image that correspond to features within the simulated refined image aligning an image of the plurality of image with the aligned binarized image; and placing, based on the identified features, markers on the aligned image, each marker being placed at a location associated with a local minima of the intensity within the image around the identified feature. In an embodiment, the binarized image can be obtained via denoising processes and thresholding process as discussed above.

In an embodiment, the placing of the markers includes determining a contour of an identified feature within the binarized image; aligning the contour with a corresponding feature in the image of the plurality of images 1601; and identifying locations of a pair of markers around the contour, a first marker is at a local minima of image intensity inside the contour, and a second marker is another local minima of the image intensity outside the contour.

In an embodiment, the identifying of the pair of markers includes determining the first marker, in a specified direction toward the inside of the contour, the local minima of the intensity of the image; and determining the second marker, in the specified direction toward the outside of the contour and across a local maxima of the intensity of the image, another local minima of the intensity of the image.

Process P1703 includes summing image intensities of the plurality of refined images 1701. Process P1705 includes dividing the summed image intensities by the total number of refined images 1701 to generate the printability map 1615 associated with the mask pattern. For example, the plurality of refined images 1701 can be stacked and each corresponding pixels of the stacked images can be summed. The summed intensity associated with each pixel can be divided by a total number of the plurality of images 1601.

Furthermore, the method 1700 can include process P1607 for determining values 1617 of one or more parameters (e.g., OPC data, dose, focus, source parameters, pupils parameters, etc.) associated with the patterning process as discussed above.

In an embodiment, referring to FIG. 12C, another flow chart is provided for a method 1800 for generating a printability map associated with a mask pattern. The method 1700 includes following processes P1801, P1803, and P1805 discussed in detail below.

Process P1801 includes obtaining a plurality of binary images 1801 of a patterned substrate based on features of the mask pattern. In an embodiment, the plurality of binary images 1801 are obtained by applying a binarization algorithm to each of a plurality of images 1601 of the patterned substrate. In an embodiment, the binarization algorithm is configured to generate a binary image for a given image of the plurality of images 1601 based on features in the given image that correspond to the features of the mask pattern. In an embodiment, the features within each of the plurality of images 1601 corresponding features of the mask pattern are identified based on a simulated image of the patterned substrate, for example, as discussed with respect to FIG. 15A.

In an embodiment, the binarization algorithm comprises thresholding of each of the plurality of images 1601 of the patterned substrate, the thresholding being based on the features corresponding to the mask pattern. In an embodiment, the thresholding can be an adaptive thresholding or a single value thresholding. In an embodiment, the thresholding refers to applying a threshold value associated with a pixel intensity to a given image. Accordingly, if a pixel intensity of the given image is below the intensity threshold, the pixel is assigned a value of 0 (e.g., indicative of not printing) and if the pixel intensity is above the intensity threshold, the pixel is assigned a value of 1 (e.g., indicative of printing) or vice-versa. Hence, a binary image is obtained. In an embodiment, the thresholding can be applied to a portion of the image around the features corresponding to the mask pattern. For the remaining portions, the pixels may be simply assigned a value 0 (e.g., indicative of not printing), irrespective of whether the threshold intensity is breached or not.

In an embodiment, the binarization algorithm is a watershed algorithm configured to perform image segmentation based on markers placed within the plurality of images 1601. In an embodiment, the markers includes a first marker and a second marker. The first marker can be, in a specified direction toward the inside of the contour, at a local minima of the intensity of the image. The second marker can be, in the specified direction toward the outside of the contour and across a local maxima of the intensity of the image, at another local minima of the intensity of the image. For example, FIG. 15A illustrate example markers Me1, Mi1, Mi2 around features Fe1, as discussed earlier.

It can be appreciated that the markers or markings discussed herein based on local minima are only exemplary to illustrate the concepts of the present disclosure. A person of ordinary skill in the art can specify different markers based on, for example, user defined locations, feature contours, metric derived based on image intensities, or other markings related to image segmentation.

Process P1803 includes aligning the plurality of binary images 1801 and summing intensities of the plurality of binary images 1801. Process P1805 includes dividing the summed image intensities by the total number of binary images to generate the printability map 1605 associated with the mask pattern. In an embodiment, each pixel intensity of the printability map 1605 is indicative of a probability that a feature of the mask pattern will print on a substrate.

Furthermore, the method 1800 can include process P1607 for determining values 1617 of one or more parameters (e.g., OPC data, dose, focus, source parameters, pupils parameters, etc.) associated with the patterning process as discussed above.

In an embodiment, the processes of the method 1600 can be included in a non-transitory computer-readable media. In an embodiment, there is provided a non-transitory computer-readable media comprising instructions for generating a printability map associated with a mask pattern that, the computer-readable media when executed by one or more processors, cause operations including obtaining (i) a plurality of images of a patterned substrate, (ii) a plurality of refined images based on the plurality of images, and (iii) a simulated refined image based on the mask pattern; marking each of the plurality of images based on the plurality of the refined images, the simulated refined image, and an intensity of pixels within each of the plurality of images; and generating, based on the markings, the printability map associated with the mask pattern. In an embodiment, the printability map is a spatial distribution of probability values indicating likelihood that features of the pattern will be printed on a substrate.

In an embodiment, the obtaining of the plurality of images includes instructions comprising receiving, via a metrology tool, the plurality of images of the pattern printed on the substrate; or capturing, via the metrology tool, the plurality of images of the pattern printed on the substrate. In an embodiment, one or more refined images of the plurality of refined images are one or more binary images. In an embodiment, the simulated refined image is a binary image. In an embodiment, the plurality of images are obtained via a scanning electron microscope (SEM) of a patterned substrate. In an embodiment, each image of the plurality of images is a SEM image.

In an embodiment, the obtaining of the plurality of refined images includes denoising the plurality of images; and converting, via an adaptive thresholding algorithm, each of the denoised plurality of images to a refined image, the adaptive thresholding algorithm adaptively finding an optimal threshold to distinguish printing and not printing areas within an image. In an embodiment, the adaptive thresholding algorithm is an Otsu thresholding algorithm configured to receive the plurality of images or the denoised plurality of images and the markers within each of the plurality of images as input and output a refined image.

In an embodiment, the denoising of the plurality of images include instructions comprising applying a first median filter and a Gaussian filter to each of the plurality of images to such that a ridge edge accuracy associated with each of the plurality of images is maintained, the first median filter characterized by a first kernel size; applying a second median filter to enhance image contrast of each of the plurality of images, the image contrast being between printing area and not printing area, the second median filter characterized by a second kernel size, the second kernel size being greater than the first kernel size; and applying a third filter to further decrease noise in the plurality of images, the third filter characterized by a third kernel size.

In an embodiment, the obtaining of the simulated refined image includes executing one or more process models of the patterning process using the mask pattern and process conditions corresponding to each of the plurality of images to generate the simulated image of a pattern that will be printed on a substrate; and applying a selected threshold intensity value to the simulated image to generate the simulated refined image.

In an embodiment, the marking of each of the plurality of images includes aligning a refined image of the plurality of the refined images with the simulated refined image; identifying features within the refined image that correspond to features within the simulated refined image; aligning an image of the plurality of image with the aligned refined image; and placing, based on the identified features, markers on the aligned image, each marker being placed at a location associated with a local minima of the intensity within the image around the identified feature.

In an embodiment, the placing of the markers include determining a contour of an identified feature within the refined image; aligning the contour with a corresponding feature in the image of the plurality of images; and identifying locations of a pair of markers around the contour in a e.g., normal direction to the contour. The first marker being at local minima of image intensity inside the contour, and a second marker being at the local minima of the image profile along e.g., the normal direction found outside the contour.

In an embodiment, the generating of the plurality of pair of markers includes determining the first marker, along the normal direction toward the inside of the contour, the local minima of the intensity of the image; determining the second marker, along the normal direction toward the outside of the contour and across a local maxima of the intensity of the image, another local minima of the intensity of the image.

In an embodiment, the generating of the printability map includes inputting the marks of the plurality of images to an algorithm configured to generate a plurality of another refined images corresponding to each image of the plurality of images; aligning the plurality of another refined images with respect to each other; and generating, based on intensity values of the aligned plurality of another refined images, the printability map for at least one of the plurality of another refined images.

In an embodiment, the algorithm is a watershed algorithm configured to perform image segmentation based on the markers placed within the plurality of images. In an embodiment, a model such as a convolutional neural network may also be used. The convolutional neural network is configured to generate a refined image based on the plurality of images and the markers within the plurality of images.

In an embodiment, the generating of the printability map includes determining a probability value of each pixel of the printability map by: summing the image intensity of another refined images of the plurality of refined images; and dividing the image intensity of the summed image by the total number of refined images.

In an embodiment, the computer-readable media includes instructions for generating values of one or more parameters of the patterning process based on the printability map.

In an embodiment, the generating of the values includes inputting the printability map associated with the mask pattern. to an optical proximity correction (OPC) process; determining a probability associated an assist feature of the mask pattern from the printability map, the probability indicative of whether the assist feature will print on a substrate; generating, based on the probability of the assist feature, OPC data to adjust one or more main features, or one or more assist features of the mask pattern to minimize the probability that the assist feature will print on the substrate.

In an embodiment, the generating of the OPC data includes adjusting, via the OPC simulation process associated with the patterning process, a shape and/or size of the one or more main features, or the one or more assist features of the mask pattern, the adjusted shape and/or size reducing the probability that an assist feature will print on the substrate; or removing, via the OPC simulation process associated with the patterning process, the one or more assist features of the mask pattern.

In an embodiment, the generating includes determining, based on the printability map, parameters associated with a source and/or a mask pattern to reduce the probability that an assist feature will print. In an embodiment, the determining of the source and/or the mask pattern includes adjusting, via a source mask optimization (SMO) process, source parameters and/or mask parameters to cause reduction in the probability that the assist feature of the mask pattern will print on the substrate.

In an embodiment, the generating includes adjusting, based on the printability map, one or more parameters associated with a patterning apparatus used for patterning the substrate to cause a reduction in the probability that an assist feature will print on the substrate. In an embodiment, the one or more parameters comprises: dose of a scanner, focus of the scanner, and/or a substrate table height.

In an embodiment, there is further provided, a non-transitory computer-readable media comprising instructions for generating a printability map associated with a mask pattern that, the computer-readable media when executed by one or more processors, cause operations including obtaining a plurality of refined images of a patterned substrate based on markings of a plurality of images of a patterned substrate, the markings of each image of the plurality of images being associated with an intensity of a pixel of the each image; summing image intensities of the plurality of refined images; and dividing the summed image intensities by the total number of refined images to generate the printability map associated with the mask pattern. The plurality of refined images are obtained as discussed above, for example, via the watershed algorithm. Also, the process of marking an image of the plurality of images (e.g., SEM image) of a pattered substrate is discussed above.

In some embodiments, the inspection apparatus or the metrology apparatus may be a scanning electron microscope (SEM) that yields an image of a structure (e.g., some or all the structure of a device) exposed or transferred on the substrate. FIG. 16 depicts an embodiment of a SEM tool. A primary electron beam EBP emitted from an electron source ESO is converged by condenser lens CL and then passes through a beam deflector EBD1, an E×B deflector EBD2, and an objective lens OL to irradiate a substrate PSub on a substrate table ST at a focus.

When the substrate PSub is irradiated with electron beam EBP, secondary electrons are generated from the substrate PSub. The secondary electrons are deflected by the E×B deflector EBD2 and detected by a secondary electron detector SED. A two-dimensional electron beam image can be obtained by detecting the electrons generated from the sample in synchronization with, e.g., two dimensional scanning of the electron beam by beam deflector EBD1 or with repetitive scanning of electron beam EBP by beam deflector EBD1 in an X or Y direction, together with continuous movement of the substrate PSub by the substrate table ST in the other of the X or Y direction.

A signal detected by secondary electron detector SED is converted to a digital signal by an analog/digital (A/D) converter ADC, and the digital signal is sent to an image processing system IPU. In an embodiment, the image processing system IPU may have memory MEM to store all or part of digital images for processing by a processing unit PU. The processing unit PU (e.g., specially designed hardware or a combination of hardware and software) is configured to convert or process the digital images into datasets representative of the digital images. Further, image processing system IPU may have a storage medium STOR configured to store the digital images and corresponding datasets in a reference database. A display device DIS may be connected with the image processing system IPU, so that an operator can conduct necessary operation of the equipment with the help of a graphical user interface.

As noted above, SEM images may be processed to extract contours that describe the edges of objects, representing device structures, in the image. These contours are then quantified via metrics, such as CD. Thus, typically, the images of device structures are compared and quantified via simplistic metrics, such as an edge-to-edge distance (CD) or simple pixel differences between images. Typical contour models that detect the edges of the objects in an image in order to measure CD use image gradients. Indeed, those models rely on strong image gradients. But, in practice, the image typically is noisy and has discontinuous boundaries. Techniques, such as smoothing, adaptive thresholding, edge-detection, erosion, and dilation, may be used to process the results of the image gradient contour models to address noisy and discontinuous images, but will ultimately result in a low-resolution quantification of a high-resolution image. Thus, in most instances, mathematical manipulation of images of device structures to reduce noise and automate edge detection results in loss of resolution of the image, thereby resulting in loss of information. Consequently, the result is a low-resolution quantification that amounts to a simplistic representation of a complicated, high-resolution structure.

So, it is desirable to have a mathematical representation of the structures (e.g., circuit features, alignment mark or metrology target portions (e.g., grating features), etc.) produced or expected to be produced using a patterning process, whether, e.g., the structures are in a latent resist image, in a developed resist image or transferred to a layer on the substrate, e.g., by etching, that can preserve the resolution and yet describe the general shape of the structures. In the context of lithography or other pattering processes, the structure may be a device or a portion thereof that is being manufactured and the images may be SEM images of the structure. In some instances, the structure may be a feature of semiconductor device, e.g., integrated circuit. In this case, the structure may be referred as a pattern or a desired pattern that comprises a plurality of feature of the semiconductor device. In some instances, the structure may be an alignment mark, or a portion thereof (e.g., a grating of the alignment mark), that is used in an alignment measurement process to determine alignment of an object (e.g., a substrate) with another object (e.g., a patterning device) or a metrology target, or a portion thereof (e.g., a grating of the metrology target), that is used to measure a parameter (e.g., overlay, focus, dose, etc.) of the patterning process. In an embodiment, the metrology target is a diffractive grating used to measure, e.g., overlay.

FIG. 17 schematically illustrates a further embodiment of an inspection apparatus. The system is used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In an embodiment, the charged particle beam generator 81, the condenser lens module 82 and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in an embodiment, the monitoring module 87 is configured or programmed to cause execution of a method described herein. In an embodiment, the monitoring module 87 comprises a computing device. In an embodiment, the monitoring module 87 comprises a computer program to provide functionality herein and encoded on a computer readable medium forming, or disposed within, the monitoring module 87.

In an embodiment, like the electron beam inspection tool of FIG. 16 that uses a probe to inspect a substrate, the electron current in the system of FIG. 17 is significantly larger compared to, e.g., a CD SEM such as depicted in FIG. 16, such that the probe spot is large enough so that the inspection speed can be fast. However, the resolution may not be as high as compared to a CD SEM because of the large probe spot. In an embodiment, the above discussed inspection apparatus may be single beam or a multi-beam apparatus without limiting the scope of the present disclosure.

The SEM images, from, e.g., the system of FIG. 16 and/or FIG. 17, may be processed to extract contours that describe the edges of objects, representing device structures, in the image. These contours are then typically quantified via metrics, such as CD, at user-defined cut-lines. Thus, typically, the images of device structures are compared and quantified via metrics, such as an edge-to-edge distance (CD) measured on extracted contours or simple pixel differences between images.

In an embodiment, the one or more procedures of the process 300, 1400 and/or 1500 can be implemented as instructions (e.g., program code) in a processor of a computer system (e.g., process 104 of computer system 100). In an embodiment, the procedures may be distributed across a plurality of processors (e.g., parallel computation) to improve computing efficiency. In an embodiment, the computer program product comprising a non-transitory computer readable medium has instructions recorded thereon, the instructions when executed by a computer hardware system implementing the method 300, 1400, or 1500, in conjunction with methods related to FIGS. 2, and 14-17.

According to present disclosure, the combination and sub-combinations of disclosed elements constitute separate embodiments. For example, a first combination includes determining likelihood of printing of an assist feature (e.g., SRAF) on a substrate. The sub-combination may include determining a model configured to predict variance data associated with a given mask image, the mask image including an assist feature. In another example, the combination includes determining OPC, or SMO based on model-generated variance data. In another example, the combination includes determining, based on the variance data, process adjustments to a lithography process, resist process, or etch process so that the probability of printing an assist feature (SRAF) is minimized.

In an embodiment, the corrections and post-OPC images determined using results (e.g., variance data) of methods 300 and 1400, may be employed in optimization of patterning process or adjusting parameters of the patterning process. As an example, OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, especially in the context of lithography simulation/optimization, the term “mask”/“patterning device” and “design layout” can be used interchangeably, as in lithography simulation/optimization, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another and/or non-geometrical optical effects such as diffraction and interference. Similarly, proximity effects may arise from diffusion and other chemical effects during post-exposure bake (PEB), resist development, and etching that generally follow lithography.

In order to ensure that the projected image of the design layout is in accordance with requirements of a given target circuit design, proximity effects need to be predicted and compensated for, using sophisticated numerical models, corrections or pre-distortions of the design layout. The article “Full-Chip Lithography Simulation and Design Analysis—How OPC Is Changing IC Design”, C. Spence, Proc. SPIE, Vol. 5751, pp 1-14 (2005) provides an overview of current “model-based” optical proximity correction processes. In a typical high-end design almost every feature of the design layout has some modification in order to achieve high fidelity of the projected image to the target design. These modifications may include shifting or biasing of edge positions or line widths as well as application of “assist” features that are intended to assist projection of other features.

Application of model-based OPC to a target design involves good process models and considerable computational resources, given the many millions of features typically present in a chip design. However, applying OPC is generally not an “exact science”, but an empirical, iterative process that does not always compensate for all possible proximity effect. Therefore, effect of OPC, e.g., design layouts after application of OPC and any other RET, need to be verified by design inspection, i.e. intensive full-chip simulation using calibrated numerical process models, in order to minimize the possibility of design flaws being built into the patterning device pattern. This is driven by the enormous cost of making high-end patterning devices, which run in the multi-million dollar range, as well as by the impact on turn-around time by reworking or repairing actual patterning devices once they have been manufactured.

Both OPC and full-chip RET verification may be based on numerical modeling systems and methods as described, for example in, U.S. patent application Ser. No. 10/815,573 and an article titled “Optimized Hardware and Software For Fast, Full Chip Simulation”, by Y. Cao et al., Proc. SPIE, Vol. 5754, 405 (2005).

One RET is related to adjustment of the global bias of the design layout. The global bias is the difference between the patterns in the design layout and the patterns intended to print on the substrate. For example, a circular pattern of 25 nm diameter may be printed on the substrate by a 50 nm diameter pattern in the design layout or by a 20 nm diameter pattern in the design layout but with high dose.

In addition to optimization to design layouts or patterning devices (e.g., OPC), the illumination source can also be optimized, either jointly with patterning device optimization or separately, in an effort to improve the overall lithography fidelity. The terms “illumination source” and “source” are used interchangeably in this document. Since the 1990s, many off-axis illumination sources, such as annular, quadrupole, and dipole, have been introduced, and have provided more freedom for OPC design, thereby improving the imaging results, As is known, off-axis illumination is a proven way to resolve fine structures (i.e., target features) contained in the patterning device. However, when compared to a traditional illumination source, an off-axis illumination source usually provides less radiation intensity for the aerial image (AI). Thus, it becomes desirable to attempt to optimize the illumination source to achieve the optimal balance between finer resolution and reduced radiation intensity.

Numerous illumination source optimization approaches can be found, for example, in an article by Rosenbluth et al., titled “Optimum Mask and Source Patterns to Print A Given Shape”, Journal of Microlithography, Microfabrication, Microsystems 1(1), pp. 13-20, (2002). The source is partitioned into several regions, each of which corresponds to a certain region of the pupil spectrum. Then, the source distribution is assumed to be uniform in each source region and the brightness of each region is optimized for process window. However, such an assumption that the source distribution is uniform in each source region is not always valid, and as a result the effectiveness of this approach suffers. In another example set forth in an article by Granik, titled “Source Optimization for Image Fidelity and Throughput”, Journal of Microlithography, Microfabrication, Microsystems 3(4), pp. 509-522, (2004), several existing source optimization approaches are overviewed and a method based on illuminator pixels is proposed that converts the source optimization problem into a series of non-negative least square optimizations. Though these methods have demonstrated some successes, they typically require multiple complicated iterations to converge. In addition, it may be difficult to determine the appropriate/optimal values for some extra parameters, such as y in Granik's method, which dictates the trade-off between optimizing the source for substrate image fidelity and the smoothness requirement of the source.

For low k₁ photolithography, optimization of both the source and patterning device is useful to ensure a viable process window for projection of critical circuit patterns. Some algorithms (e.g. Socha et. al. Proc. SPIE vol. 5853, 2005, p. 180) discretize illumination into independent source points and mask into diffraction orders in the spatial frequency domain, and separately formulate a cost function (which is defined as a function of selected design variables) based on process window metrics such as exposure latitude which could be predicted by optical imaging models from source point intensities and patterning device diffraction orders. The term “design variables” as used herein comprises a set of parameters of a lithographic projection apparatus or a lithographic process, for example, parameters a user of the lithographic projection apparatus can adjust, or image characteristics a user can adjust by adjusting those parameters. It should be appreciated that any characteristics of a lithographic projection process, including those of the source, the patterning device, the projection optics, and/or resist characteristics can be among the design variables in the optimization. The cost function is often a non-linear function of the design variables. Then standard optimization techniques are used to minimize the cost function.

Relatedly, the pressure of ever decreasing design rules have driven semiconductor chipmakers to move deeper into the low k₁ lithography era with existing 193 nm ArF lithography. Lithography towards lower k₁ puts heavy demands on RET, exposure tools, and the need for litho-friendly design. 1.35 ArF hyper numerical aperture (NA) exposure tools may be used in the future. To help ensure that circuit design can be produced on to the substrate with workable process window, source-patterning device optimization (referred to herein as source-mask optimization or SMO) is becoming a significant RET for 2×nm node.

A source and patterning device (design layout) optimization method and system that allows for simultaneous optimization of the source and patterning device using a cost function without constraints and within a practicable amount of time is described in a commonly assigned International Patent Application No. PCT/US2009/065359, filed on Nov. 20, 2009, and published as WO2010/059954, titled “Fast Freeform Source and Mask Co-Optimization Method”, which is hereby incorporated by reference in its entirety.

Another source and mask optimization method and system that involves optimizing the source by adjusting pixels of the source is described in a commonly assigned U.S. patent application Ser. No. 12/813,456, filed on Jun. 10, 2010, and published as U.S. Patent Application Publication No. 2010/0315614, titled “Source-Mask Optimization in Lithographic Apparatus”, which is hereby incorporated by reference in its entirety.

In a lithographic projection apparatus, as an example, a cost function is expressed as

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) \qquad ( Eq . 1 )$$

wherein (z₁, z₂, . . . , z_{N}) are N design variables or values thereof. ƒₚ (z₁, z₂, . . . , z_{N}) can be a function of the design variables (z₁, z₂, . . . , z_{N}) such as a difference between an actual value and an intended value of a characteristic at an evaluation point for a set of values of the design variables of (z₁, z₂, . . . , z_{N}). wₚ is a weight constant associated with ƒₚ (z₁, z₂, . . . , z_{N}). An evaluation point or pattern more critical than others can be assigned a higher wₚ value. Patterns and/or evaluation points with larger number of occurrences may be assigned a higher wₚ value, too. Examples of the evaluation points can be any physical point or pattern on the substrate, any point on a virtual design layout, or resist image, or aerial image, or a combination thereof. ƒₚ (z₁, z₂, . . . , z_{N}) can also be a function of one or more stochastic effects such as the LWR, which are functions of the design variables (z₁, z₂, . . . , z_{N}). The cost function may represent any suitable characteristics of the lithographic projection apparatus or the substrate, for instance, failure rate of a feature, focus, CD, image shift, image distortion, image rotation, stochastic effects, throughput, CDU, or a combination thereof. CDU is local CD variation (e.g., three times of the standard deviation of the local CD distribution). CDU may be interchangeably referred to as LCDU. In one embodiment, the cost function represents (i.e., is a function of) CDU, throughput, and the stochastic effects. In one embodiment, the cost function represents (i.e., is a function of) EPE, throughput, and the stochastic effects. In one embodiment, the design variables (z₁, z₂, . . . , z_{N}) comprise dose, global bias of the patterning device, shape of illumination from the source, or a combination thereof. Since it is the resist image that often dictates the circuit pattern on a substrate, the cost function often includes functions that represent some characteristics of the resist image. For example, ƒₚ (z₁, z₂, . . . , z_{N}) of such an evaluation point can be simply a distance between a point in the resist image to an intended position of that point (i.e., edge placement error EPEₚ(z₁, z₂, . . . , z_{N})). The design variables can be any adjustable parameters such as adjustable parameters of the source, the patterning device, the projection optics, dose, focus, etc. The projection optics may include components collectively called as “wavefront manipulator” that can be used to adjust shapes of a wavefront and intensity distribution and/or phase shift of the irradiation beam. The projection optics preferably can adjust a wavefront and intensity distribution at any location along an optical path of the lithographic projection apparatus, such as before the patterning device, near a pupil plane, near an image plane, near a focal plane. The projection optics can be used to correct or compensate for certain distortions of the wavefront and intensity distribution caused by, for example, the source, the patterning device, temperature variation in the lithographic projection apparatus, thermal expansion of components of the lithographic projection apparatus. Adjusting the wavefront and intensity distribution can change values of the evaluation points and the cost function. Such changes can be simulated from a model or actually measured. Of course, CF (z₁, z₂, . . . , z_{N}) is not limited the form in Eq. 1. CF (z₁, z₂, . . . , z_{N}) can be in any other suitable form.

It should be noted that the normal weighted root mean square (RMS) of ƒₚ(z₁, z₂, . . . , z_{N}) is defined as

$$\sqrt{\frac{1}{P} {\sum }_{p = 1}^{P} {w}_{p} {f}_{p}^{2} ( {z}_{1} , {z}_{2} , … , {z}_{N} )} ,$$

therefore, minimizing the weighted RMS of ƒₚ (z₁, z₂, . . . , z_{N}) is equivalent to minimizing the cost function

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) ,$$

defined in Eq. 1. Thus the weighted RMS of ƒₚ (z₁, z₂, . . . , z_{N}) and Eq. 1 may be utilized interchangeably for notational simplicity herein.

Further, if considering maximizing the PW (Process Window), one can consider the same physical location from different PW conditions as different evaluation points in the cost function in (Eq. 1). For example, if considering N PW conditions, then one can categorize the evaluation points according to their PW conditions and write the cost functions as:

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) = {\sum }_{u = 1}^{U} {\sum }_{{p}_{u} = 1}^{{P}_{u}} {w}_{{p}_{u}} {f}_{{p}_{u}}^{2} ( {z}_{1} , {z}_{2} , … , z ) \qquad ( Eq . {1}^{′} )$$

Where ƒₚ_{ᵤ}(z₁, z₂, . . . , z_{N}) is the value of ƒₚ (z₁, z₂, . . . , z_{N}) under the u-th PW condition u=1, . . . , U. When ƒₚ (z₁, z₂, . . . , z_{N}) is the EPE, then minimizing the above cost function is equivalent to minimizing the edge shift under various PW conditions, thus this leads to maximizing the PW. In particular, if the PW also consists of different mask bias, then minimizing the above cost function also includes the minimization of MEEF (Mask Error Enhancement Factor), which is defined as the ratio between the substrate EPE and the induced mask edge bias.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. The desired throughput may limit the dose and thus has implications for the stochastic effects (e.g., imposing a lower bound on the stochastic effects). Higher throughput generally leads to lower dose, shorter longer exposure time and greater stochastic effects. Consideration of substrate throughput and minimization of the stochastic effects may constrain the possible values of the design variables because the stochastic effects are function of the design variables. Without such a constraint imposed by the desired throughput, the optimization may yield a set of values of the design variables that are unrealistic. For example, if the dose is among the design variables, without such a constraint, the optimization may yield a dose value that makes the throughput economically impossible. However, the usefulness of constraints should not be interpreted as a necessity. The throughput may be affected by the failure rate based adjustment to parameters of the patterning process. It is desirable to have lower failure rate of the feature while maintaining a high throughput. Throughput may also be affected by the resist chemistry. Slower resist (e.g., a resist that requires higher amount of light to be properly exposed) leads to lower throughput. Thus, based on the optimization process involving failure rate of a feature due to resist chemistry or fluctuations, and dose requirements for higher throughput, appropriate parameters of the patterning process may be determined.

The optimization process therefore is to find a set of values of the design variables, under the constraints (z₁, z₂, . . . , z_{N})∈Z, that minimize the cost function, i.e., to find

$$( {\tilde{z}}_{1} , {\tilde{z}}_{2} , … , {\tilde{z}}_{N} ) = {arg min}_{( {z}_{1} , {z}_{2} , … , {z}_{N} ) ∈ Z} CF ( {z}_{1} , {z}_{2} , … , {z}_{N} ) = {arg min}_{( {z}_{1} , {z}_{2} , … , {z}_{N} ) ∈ Z} {\sum }_{p = 1}^{P} {w}_{p} {f}_{p}^{2} ( {z}_{1} , {z}_{2} , … , {z}_{N} ) \qquad ( Eq . 2 )$$

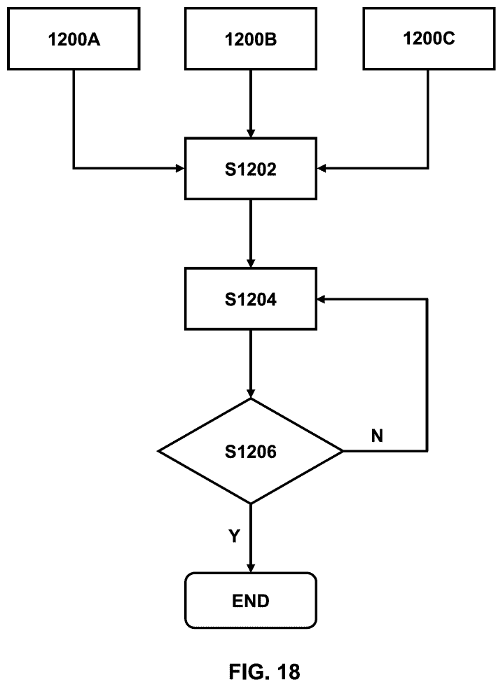

A general method of optimizing the lithography projection apparatus, according to an embodiment, is illustrated in FIG. 18. This method comprises a step S1202 of defining a multi-variable cost function of a plurality of design variables. The design variables may comprise any suitable combination selected from characteristics of the illumination source (1200A) (e.g., pupil fill ratio, namely percentage of radiation of the source that passes through a pupil or aperture), characteristics of the projection optics (1200B) and characteristics of the design layout (1200C). For example, the design variables may include characteristics of the illumination source (1200A) and characteristics of the design layout (1200C) (e.g., global bias) but not characteristics of the projection optics (1200B), which leads to an SMO. Alternatively, the design variables may include characteristics of the illumination source (1200A), characteristics of the projection optics (1200B) and characteristics of the design layout (1200C), which leads to a source-mask-lens optimization (SMLO). In step S1204, the design variables are simultaneously adjusted so that the cost function is moved towards convergence. In step S1206, it is determined whether a predefined termination condition is satisfied. The predetermined termination condition may include various possibilities, i.e. the cost function may be minimized or maximized, as required by the numerical technique used, the value of the cost function has been equal to a threshold value or has crossed the threshold value, the value of the cost function has reached within a preset error limit, or a preset number of iteration is reached. If either of the conditions in step S1206 is satisfied, the method ends. If none of the conditions in step S1206 is satisfied, the step S1204 and S1206 are iteratively repeated until a desired result is obtained. The optimization does not necessarily lead to a single set of values for the design variables because there may be physical restraints caused by factors such as the failure rates, the pupil fill factor, the resist chemistry, the throughput, etc. The optimization may provide multiple sets of values for the design variables and associated performance characteristics (e.g., the throughput) and allows a user of the lithographic apparatus to pick one or more sets.

In a lithographic projection apparatus, the source, patterning device and projection optics can be optimized alternatively (referred to as Alternative Optimization) or optimized simultaneously (referred to as Simultaneous Optimization). The terms “simultaneous”, “simultaneously”, “joint” and “jointly” as used herein mean that the design variables of the characteristics of the source, patterning device, projection optics and/or any other design variables, are allowed to change at the same time. The term “alternative” and “alternatively” as used herein mean that not all of the design variables are allowed to change at the same time.

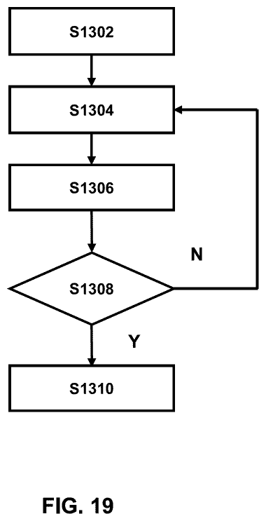

In FIG. 19, the optimization of all the design variables is executed simultaneously. Such flow may be called the simultaneous flow or co-optimization flow. Alternatively, the optimization of all the design variables is executed alternatively, as illustrated in FIG. 19. In this flow, in each step, some design variables are fixed while the other design variables are optimized to minimize the cost function; then in the next step, a different set of variables are fixed while the others are optimized to minimize the cost function. These steps are executed alternatively until convergence or certain terminating conditions are met.

As shown in the non-limiting example flowchart of FIG. 19, first, a design layout (step S1302) is obtained, then a step of source optimization is executed in step S1304, where all the design variables of the illumination source are optimized (SO) to minimize the cost function while all the other design variables are fixed. Then in the next step S1306, a mask optimization (MO) is performed, where all the design variables of the patterning device are optimized to minimize the cost function while all the other design variables are fixed. These two steps are executed alternatively, until certain terminating conditions are met in step S1308. Various termination conditions can be used, such as, the value of the cost function becomes equal to a threshold value, the value of the cost function crosses the threshold value, the value of the cost function reaches within a preset error limit, or a preset number of iteration is reached, etc. Note that SO-MO-Alternative-Optimization is used as an example for the alternative flow. The alternative flow can take many different forms, such as SO-LO-MO-Alternative-Optimization, where SO, LO (Lens Optimization) is executed, and MO alternatively and iteratively; or first SMO can be executed once, then execute LO and MO alternatively and iteratively; and so on. Finally the output of the optimization result is obtained in step S1310, and the process stops.

The pattern selection algorithm, as discussed before, may be integrated with the simultaneous or alternative optimization. For example, when an alternative optimization is adopted, first a full-chip SO can be performed, the ‘hot spots’ and/or ‘warm spots’ are identified, then an MO is performed. In view of the present disclosure numerous permutations and combinations of sub-optimizations are possible in order to achieve the desired optimization results.

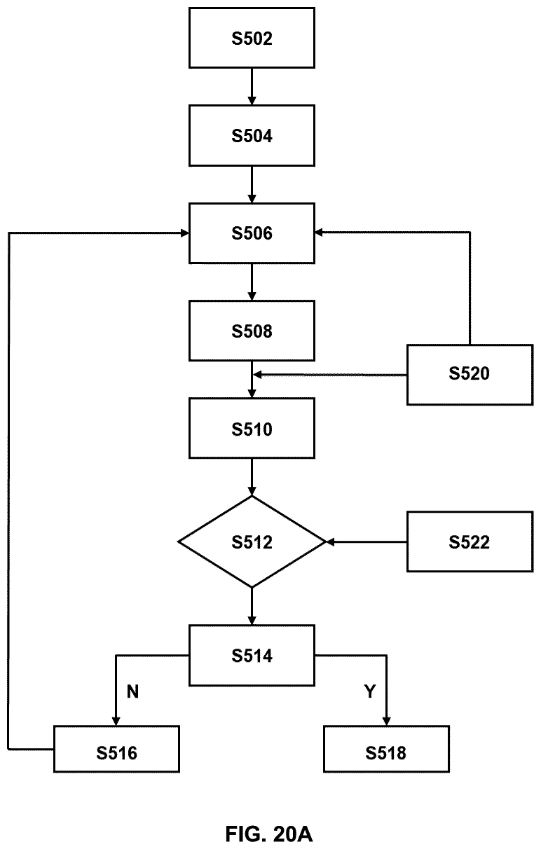

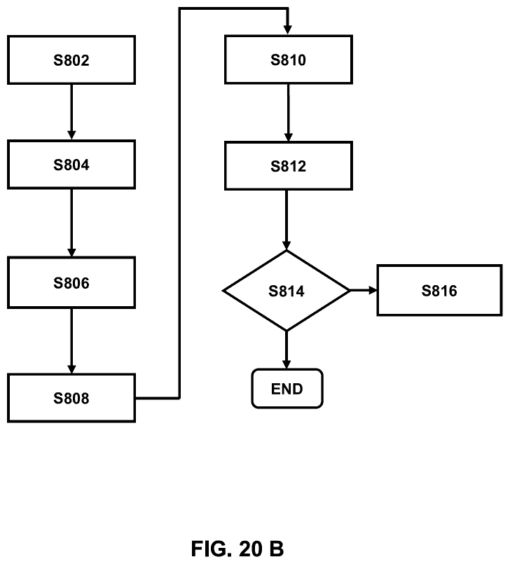

FIG. 20A shows one exemplary method of optimization, where a cost function is minimized. In step S502, initial values of design variables are obtained, including their tuning ranges, if any. In step S504, the multi-variable cost function is set up. In step S506, the cost function is expanded within a small enough neighborhood around the starting point value of the design variables for the first iterative step (i=0). In step S508, standard multi-variable optimization techniques are applied to minimize the cost function. Note that the optimization problem can apply constraints, such as tuning ranges, during the optimization process in S508 or at a later stage in the optimization process. Step S520 indicates that each iteration is done for the given test patterns (also known as “gauges”) for the identified evaluation points that have been selected to optimize the lithographic process. In step S510, a lithographic response is predicted. In step S512, the result of step S510 is compared with a desired or ideal lithographic response value obtained in step S522. If the termination condition is satisfied in step S514, i.e. the optimization generates a lithographic response value sufficiently close to the desired value, and then the final value of the design variables is outputted in step S518. The output step may also include outputting other functions using the final values of the design variables, such as outputting a wavefront aberration-adjusted map at the pupil plane (or other planes), an optimized source map, and optimized design layout etc. If the termination condition is not satisfied, then in step S516, the values of the design variables is updated with the result of the i-th iteration, and the process goes back to step S506. The process of FIG. 20A is elaborated in details below.

In an exemplary optimization process, no relationship between the design variables (z₁, z₂, . . . , z_{N}) and ƒₚ(z₁, z₂, . . . , z_{N}) is assumed or approximated, except that ƒₚ(z₁, z₂, . . . , z_{N}) is sufficiently smooth (e.g. first order derivatives

$$\frac{\partial {f}_{p} ( {z}_{1} , {z}_{2} , … , {z}_{N} )}{\partial {z}_{n}} ,$$

(n=1, 2, . . . N) exist), which is generally valid in a lithographic projection apparatus. An algorithm, such as the Gauss-Newton algorithm, the Levenberg-Marquardt algorithm, the gradient descent algorithm, simulated annealing, the genetic algorithm, can be applied to find (\tilde{z}₁, \tilde{z}₂, . . . , \tilde{z}_{N}).

Here, the Gauss-Newton algorithm is used as an example. The Gauss-Newton algorithm is an iterative method applicable to a general non-linear multi-variable optimization problem. In the i-th iteration wherein the design variables (z₁, z₂, . . . , z_{N}) take values of (z₁ᵢ, z₂ᵢ, . . . , z_{Ni}), the Gauss-Newton algorithm linearizes ƒp (z₁, z₂, . . . , z_{N}) in the vicinity of (z₁ᵢ, z₂ᵢ, . . . , z_{Ni}), and then calculates values (z₁₍ᵢ₊₁₎, z₂₍ᵢ₊₁₎, . . . , z_{N(i+1)}) in the vicinity of (z₁ᵢ, z₂ᵢ, . . . , z_{Ni}) that give a minimum of CF(z₁, z₂, . . . , z_{N}) The design variables (z₁, z₂, . . . , z_{N}) take the values of (z₁₍ᵢ₊₁₎, z₂₍ᵢ₊₁₎, . . . , z_{N(i+1)}) in the (i+1)-th iteration. This iteration continues until convergence (i.e. CF (z₁, z₂, . . . , z_{N}) does not reduce any further) or a preset number of iterations is reached.

Specifically, in the i-th iteration, in the vicinity of (z₁ᵢ, z₂ᵢ, . . . , z_{Ni})

$${f}_{p} ( {z}_{1} , {z}_{2} , … , {z}_{N} ) \approx {f}_{p} ( {z}_{1 i} , {z}_{2 i} , … , {z}_{Ni} ) + {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … , {z}_{N} = {z}_{Ni ,}} ( {z}_{n} - {z}_{ni} ) \qquad ( Eq . 3 )$$

Under the approximation of Eq. 3, the cost function becomes:

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) = \qquad ( Eq . 4 )$$

$${\sum }_{p = 1}^{P} {w}_{p} ( {f}_{p} ( {z}_{1 i} , {z}_{2 i} , … , {z}_{Ni} ) +$$

$${{\sum }_{n = 1}^{N} \frac{\partial f ( {z}_{1} , {z}_{2} , … , {z}_{N} )}{\partial {z}_{n}} {\vert}_{{z}_{1} = {z}_{1 i} , {z}_{2} = {z}_{2 i} , … , {z}_{N} = {z}_{Ni ,}} ( {z}_{n} - {z}_{ni} ) )}^{2}$$

which is a quadratic function of the design variables (z₁, z₂, . . . , z_{N}). Every term is constant except the design variables (z₁, z₂, . . . , z_{N}).

If the design variables (z₁, z₂, . . . , z_{N}) are not under any constraints, (z₁₍ᵢ₊₁₎, z₂₍ᵢ₊₁₎, . . . , z_{N(i+1)}) can be derived by solving by N linear equations:

$$\frac{\partial CF ( {z}_{1} , {z}_{2} , … , {z}_{N} )}{\partial {z}_{n}} = 0 ,$$

wherein n=1, 2, . . . N.

If the design variables (z₁, z₂, . . . , z_{N}) are under the constraints in the form of J inequalities (e.g. tuning ranges of (z₁, z₂, . . . , z_{N}))

$${\sum }_{n = 1}^{N} {A}_{nj} {z}_{n} \leq {B}_{j} ,$$

for j=1, 2, . . . J; and K equalities (e.g. interdependence between the design variables)

$${\sum }_{n = 1}^{N} {C}_{nk} {z}_{n} = {D}_{k} ,$$

for k=1, 2, . . . K; the optimization process becomes a classic quadratic programming problem, wherein Aₙⱼ, Bⱼ, Cₙₖ, Dₖ are constants. Additional constraints can be imposed for each iteration. For example, a “damping factor” Δ_{D} can be introduced to limit the difference between (z₁₍ᵢ₊₁₎, z₂₍ᵢ₊₁₎, . . . , z_{N(i+1)}) and (z₁ᵢ, z₂ᵢ, . . . , z_{Ni}), so that the approximation of Eq. 3 holds. Such constraints can be expressed as zₙᵢ−Δ_{D}≤zₙ≤zₙᵢ+Δ_{D}. (z₁₍ᵢ₊₁₎, z₂₍ᵢ₊₁₎, . . . , z_{N(i+1)}) can be derived using, for example, methods described in Numerical Optimization (2^{nd} ed.) by Jorge Nocedal and Stephen J. Wright (Berlin New York: Vandenberghe. Cambridge University Press).

Instead of minimizing the RMS of ƒₚ (z₁, z₂, . . . , z_{N}), the optimization process can minimize magnitude of the largest deviation (the worst defect) among the evaluation points to their intended values. In this approach, the cost function can alternatively be expressed as

$$CF ( {z}_{1} , {z}_{2} , … , {z}_{N} ) = {max}_{1 \leq p \leq P} \frac{{f}_{p} ( {z}_{1} , {z}_{2} , … , {z}_{N} )}{{CL}_{p}} , \qquad ( Eq . 5 )$$

wherein CLₚ is the maximum allowed value for ƒₚ (z₁, z₂, . . . , z_{N}). This cost function represents the worst defect among the evaluation points. Optimization using this cost function minimizes magnitude of the worst defect. An iterative greedy algorithm can be used for this optimization.

The cost function of Eq. 5 can be approximated as:

$$CF ( {z}_{1} , {z}_{2} , … , {z}_{N} ) = {\sum }_{p = 1}^{P} {( \frac{{f}_{p} ( {z}_{1} , {z}_{2} , … , {z}_{N} )}{{CL}_{p}} )}^{q} , \qquad ( Eq . 6 )$$

wherein q is an even positive integer such as at least 4, preferably at least 10. Eq. 6 mimics the behavior of Eq. 5, while allowing the optimization to be executed analytically and accelerated by using methods such as the deepest descent method, the conjugate gradient method, etc.

Minimizing the worst defect size can also be combined with linearizing of ƒₚ (z₁, z₂, . . . , z_{N}). Specifically, ƒₚ (z₁, z₂, . . . , z_{N}) is approximated as in Eq. 3. Then the constraints on worst defect size are written as inequalities E_{Lp}≤ƒₚ(z₁, z₂, . . . , z_{N})≤E_{Up}, wherein E_{Lp} and E_{Up} are two constants specifying the minimum and maximum allowed deviation for the ƒₚ (z₁, z₂, . . . , z_{N}). Plugging Eq. 3 in, these constraints are transformed to, for p=1, . . . P,

$${\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … , {z}_{N} = {z}_{Ni ,}} {z}_{n} \leq {E}_{{U}_{p}} + \qquad ( Eq . {6}^{′} )$$

$${\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … , {z}_{N} = {z}_{Ni ,}} {z}_{m} - {f}_{p} ( {z}_{1 i} , {z}_{2 i} , … , {z}_{Ni} )$$

$$and$$

$$- {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … , {z}_{N} = {z}_{Ni ,}} {z}_{n} \leq \qquad ( Eq . {6}^{″} )$$

$$- {E}_{{U}_{p}} - {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … , {z}_{N} = {z}_{Ni ,}} {z}_{ni} +$$

$${f}_{p} ( {z}_{1 i} , {z}_{2 i} , … , {z}_{Ni} )$$

Since Eq. 3 is generally valid only in the vicinity of (z₁ᵢ, z₂ᵢ, . . . , z_{Ni}), in case the desired constraints E_{Lp}≤ƒₚ(z₁, z₂, . . . , z_{N})≤E_{Up} cannot be achieved in such vicinity, which can be determined by any conflict among the inequalities, the constants E_{Lp} and E_{Up} can be relaxed until the constraints are achievable. This optimization process minimizes the worst defect size in the vicinity of (z₁ᵢ, z₂ᵢ, . . . , z_{Ni}). Then each step reduces the worst defect size gradually, and each step is executed iteratively until certain terminating conditions are met. This will lead to optimal reduction of the worst defect size.

Another way to minimize the worst defect is to adjust the weight wₚ in each iteration. For example, after the i-th iteration, if the r-th evaluation point is the worst defect, wᵣ can be increased in the (i+1)-th iteration so that the reduction of that evaluation point's defect size is given higher priority.

In addition, the cost functions in Eq. 4 and Eq. 5 can be modified by introducing a Lagrange multiplier to achieve compromise between the optimization on RMS of the defect size and the optimization on the worst defect size, i.e.,

$$CF ( {z}_{1} , {z}_{2} , … , {z}_{N} ) = ( 1 - λ ) {\sum }_{p = 1}^{P} {w}_{p} {f}_{p}^{2} ( {z}_{1} , {z}_{2} , … , {z}_{N} ) + λ {max}_{1 \leq p \leq P} \frac{{f}_{p} ( {z}_{1} , {z}_{2} , … , {z}_{N} )}{{CL}_{p}} \qquad ( Eq . {6}^{′′′} )$$

where λ is a preset constant that specifies the trade-off between the optimization on RMS of the defect size and the optimization on the worst defect size. In particular, if λ=0, then this becomes Eq. 4 and the RMS of the defect size is only minimized; while if λ=1, then this becomes Eq. 5 and the worst defect size is only minimized; if 0<λ<1, then both are taken into consideration in the optimization. Such optimization can be solved using multiple methods. For example, the weighting in each iteration may be adjusted, similar to the one described previously. Alternatively, similar to minimizing the worst defect size from inequalities, the inequalities of Eq. 6′ and 6″ can be viewed as constraints of the design variables during solution of the quadratic programming problem. Then, the bounds on the worst defect size can be relaxed incrementally or increase the weight for the worst defect size incrementally, compute the cost function value for every achievable worst defect size, and choose the design variable values that minimize the total cost function as the initial point for the next step. By doing this iteratively, the minimization of this new cost function can be achieved.

Optimizing a lithographic projection apparatus can expand the process window. A larger process window provides more flexibility in process design and chip design. The process window can be defined as a set of focus and dose values for which the resist image are within a certain limit of the design target of the resist image. Note that all the methods discussed here may also be extended to a generalized process window definition that can be established by different or additional base parameters in addition to exposure dose and defocus. These may include, but are not limited to, optical settings such as NA, sigma, aberrations, polarization, or optical constants of the resist layer. For example, as described earlier, if the PW also consists of different mask bias, then the optimization includes the minimization of MEEF (Mask Error Enhancement Factor), which is defined as the ratio between the substrate EPE and the induced mask edge bias. The process window defined on focus and dose values only serve as an example in this disclosure. A method of maximizing the process window, according to an embodiment, is described below.

In a first step, starting from a known condition (ƒ₀, ε₀) in the process window, wherein ƒ₀ is a nominal focus and ε₀ is a nominal dose, minimizing one of the cost functions below in the vicinity (ƒ₀±Δƒ, ε₀±Δε):

$$CF ( {z}_{1} , {z}_{2} , … , {z}_{N} , {f}_{0} , {ε}_{0} = \qquad ( Eq . 7 )$$

$${max}_{( f , ε ) = ( {f}_{0} \pm Δ f , {ε}_{0} \pm Δ ε )} {max}_{p} \vert {f}_{p} ( {z}_{1} , {z}_{2} , … , {z}_{N} , f , ε ) \vert .$$

$$or$$

$$CF ( {z}_{1} , {z}_{2} , … , {z}_{N} , {f}_{0} , {ε}_{0} ) = {\sum }_{( f , ε ) = ( {f}_{0} \pm Δ f , {ε}_{0} \pm Δ ε )} {\sum }_{p} {w}_{p} {f}_{p}^{2} ( {z}_{1} , {z}_{2} , … , {z}_{N} , f , ε ) \qquad ( Eq . {7}^{′} )$$

$$or$$

$$CF ( {z}_{1} , {z}_{2} , … , {z}_{N} , {f}_{0} , {ε}_{0} ) = ( 1 - λ ) {\sum }_{( f , ε ) = ( {f}_{0} \pm Δ f , {ε}_{0} \pm Δ ε )} {\sum }_{p} {w}_{p} {f}_{p}^{2} ( {z}_{1} , {z}_{2} , … , {z}_{N} , f , ε ) + λ {max}_{( f , ε ) = ( {f}_{0} \pm Δ f , {ε}_{0} \pm Δ ε )} {max}_{p} \vert {f}_{p} ( {z}_{1} , {z}_{2} , … , {z}_{N} , f , ε ) \vert \qquad ( Eq . {7}^{″} )$$

If the nominal focus ƒ₀ and nominal dose ε₀ are allowed to shift, they can be optimized jointly with the design variables (z₁, z₂, . . . , z_{N}). In the next step, (ƒ₀±Δƒ, ε₀±Δε) is accepted as part of the process window, if a set of values of (z₁, z₂, . . . , z_{N}, ƒ, ε) can be found such that the cost function is within a preset limit.

Alternatively, if the focus and dose are not allowed to shift, the design variables (z₁, z₂, . . . , z_{N}) are optimized with the focus and dose fixed at the nominal focus ƒ₀ and nominal dose ε₀. In an alternative embodiment, (ƒ₀±Δƒ, ε₀±Δε) is accepted as part of the process window, if a set of values of (z₁, z₂, . . . , z_{N}) can be found such that the cost function is within a preset limit.

The methods described earlier in this disclosure can be used to minimize the respective cost functions of Eqs. 7, 7′, or 7″. If the design variables are characteristics of the projection optics, such as the Zernike coefficients, then minimizing the cost functions of Eqs. 7, 7′, or 7″ leads to process window maximization based on projection optics optimization, i.e., LO. If the design variables are characteristics of the source and patterning device in addition to those of the projection optics, then minimizing the cost function of Eqs. 7, 7′, or 7″ leads to process window maximizing based on SMLO, as illustrated in FIG. 19. If the design variables are characteristics of the source and patterning device and, then minimizing the cost functions of Eqs. 7, 7′, or 7″ leads to process window maximization based on SMO. The cost functions of Eqs. 7, 7′, or 7″ can also include at least one ƒₚ (z₁, z₂, . . . , z_{N}) such as that in Eq. 7 or Eq. 8, that is a function of one or more stochastic effects such as the LWR or local CD variation of 2D features, and throughput.

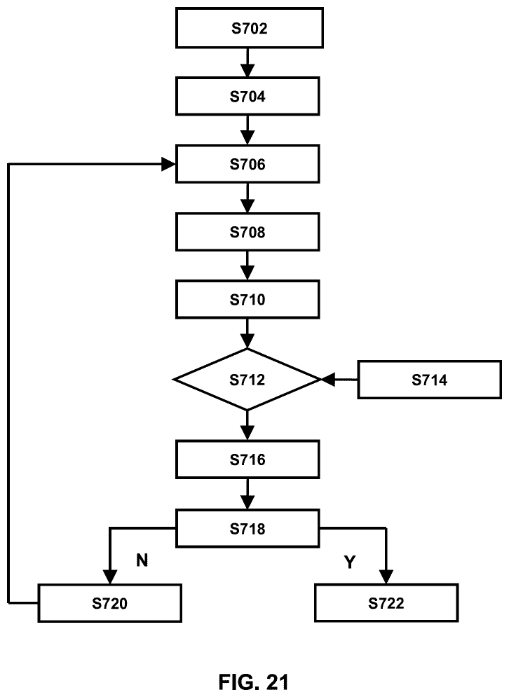

FIG. 21 shows one specific example of how a simultaneous SMLO process can use a Gauss Newton Algorithm for optimization. In step S702, starting values of design variables are identified. Tuning ranges for each variable may also be identified. In step S704, the cost function is defined using the design variables. In step S706 cost function is expanded around the starting values for all evaluation points in the design layout. In optional step S710, a full-chip simulation is executed to cover all critical patterns in a full-chip design layout. Desired lithographic response metric (such as CD or EPE) is obtained in step S714, and compared with predicted values of those quantities in step S712. In step S716, a process window is determined. Steps S718, S720, and S722 are similar to corresponding steps S514, S516 and S518, as described with respect to FIG. 20A. As mentioned before, the final output may be a wavefront aberration map in the pupil plane, optimized to produce the desired imaging performance. The final output may also be an optimized source map and/or an optimized design layout.

FIG. 20B shows an exemplary method to optimize the cost function where the design variables (z₁, z₂, . . . , z_{N}) include design variables that may only assume discrete values.

The method starts by defining the pixel groups of the illumination source and the patterning device tiles of the patterning device (step S802). Generally, a pixel group or a patterning device tile may also be referred to as a division of a lithographic process component. In one exemplary approach, the illumination source is divided into 117 pixel groups, and 94 patterning device tiles are defined for the patterning device, substantially as described above, resulting in a total of 211 divisions.

In step S804, a lithographic model is selected as the basis for photolithographic simulation. Photolithographic simulations produce results that are used in calculations of photolithographic metrics, or responses. A particular photolithographic metric is defined to be the performance metric that is to be optimized (step S806). In step S808, the initial (pre-optimization) conditions for the illumination source and the patterning device are set up. Initial conditions include initial states for the pixel groups of the illumination source and the patterning device tiles of the patterning device such that references may be made to an initial illumination shape and an initial patterning device pattern. Initial conditions may also include mask bias, NA, and focus ramp range. Although steps S802, S804, S806, and S808 are depicted as sequential steps, it will be appreciated that in other embodiments of the invention, these steps may be performed in other sequences.

In step S810, the pixel groups and patterning device tiles are ranked. Pixel groups and patterning device tiles may be interleaved in the ranking Various ways of ranking may be employed, including: sequentially (e.g., from pixel group 1 to pixel group 117 and from patterning device tile 1 to patterning device tile 94), randomly, according to the physical locations of the pixel groups and patterning device tiles (e.g., ranking pixel groups closer to the center of the illumination source higher), and according to how an alteration of the pixel group or patterning device tile affects the performance metric.

Once the pixel groups and patterning device tiles are ranked, the illumination source and patterning device are adjusted to improve the performance metric (step S812). In step S812, each of the pixel groups and patterning device tiles are analyzed, in order of ranking, to determine whether an alteration of the pixel group or patterning device tile will result in an improved performance metric. If it is determined that the performance metric will be improved, then the pixel group or patterning device tile is accordingly altered, and the resulting improved performance metric and modified illumination shape or modified patterning device pattern form the baseline for comparison for subsequent analyses of lower-ranked pixel groups and patterning device tiles. In other words, alterations that improve the performance metric are retained. As alterations to the states of pixel groups and patterning device tiles are made and retained, the initial illumination shape and initial patterning device pattern changes accordingly, so that a modified illumination shape and a modified patterning device pattern result from the optimization process in step S812.

In other approaches, patterning device polygon shape adjustments and pairwise polling of pixel groups and/or patterning device tiles are also performed within the optimization process of S812.

In an alternative embodiment the interleaved simultaneous optimization procedure may include to alter a pixel group of the illumination source and if an improvement of the performance metric is found, the dose is stepped up and down to look for further improvement. In a further alternative embodiment the stepping up and down of the dose or intensity may be replaced by a bias change of the patterning device pattern to look for further improvement in the simultaneous optimization procedure.

In step S814, a determination is made as to whether the performance metric has converged. The performance metric may be considered to have converged, for example, if little or no improvement to the performance metric has been witnessed in the last several iterations of steps S810 and S812. If the performance metric has not converged, then the steps of S810 and S812 are repeated in the next iteration, where the modified illumination shape and modified patterning device from the current iteration are used as the initial illumination shape and initial patterning device for the next iteration (step S816).

The optimization methods described above may be used to increase the throughput of the lithographic projection apparatus. For example, the cost function may include an ƒₚ (z₁, z₂, . . . , z_{N}) that is a function of the exposure time. Optimization of such a cost function is preferably constrained or influenced by a measure of the stochastic effects or other metrics. Specifically, a computer-implemented method for increasing a throughput of a lithographic process may include optimizing a cost function that is a function of one or more stochastic effects of the lithographic process and a function of an exposure time of the substrate, in order to minimize the exposure time.

In one embodiment, the cost function includes at least one ƒₚ (z₁, z₂, . . . , z_{N}) that is a function of one or more stochastic effects. The stochastic effects may include the failure of a feature, measurement data (e.g., SEPE) determined as in method of FIG. 3A, LWR or local CD variation of 2D features. In one embodiment, the stochastic effects include stochastic variations of characteristics of a resist image. For example, such stochastic variations may include failure rate of a feature, line edge roughness (LER), line width roughness (LWR) and critical dimension uniformity (CDU). Including stochastic variations in the cost function allows finding values of design variables that minimize the stochastic variations, thereby reducing risk of defects due to stochastic effects.

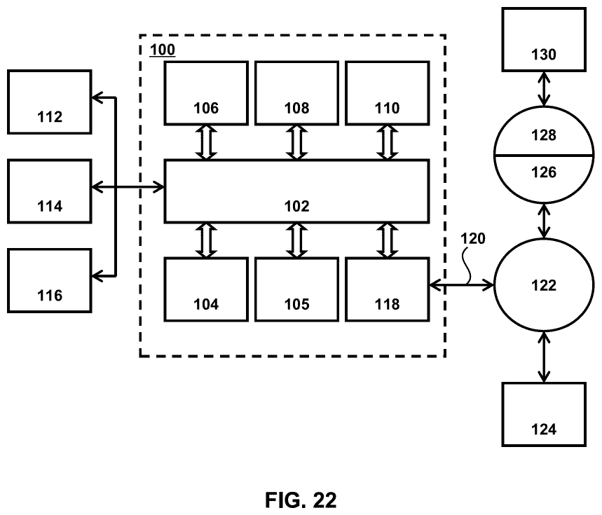

FIG. 22 is a block diagram that illustrates a computer system 100 which can assist in implementing the optimization methods and flows disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

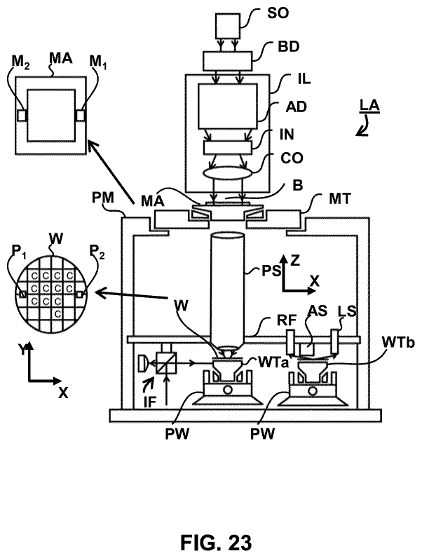

FIG. 23 schematically depicts an exemplary lithographic projection apparatus LA whose illumination source could be optimized utilizing the methods described herein. The apparatus comprises:
an illumination system IL, to condition a beam B of radiation. In this particular case, the illumination system also comprises a radiation source SO;
a first object table (e.g., mask table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive mask). However, in general, it may also be of a reflective type, for example (with a reflective mask). Alternatively, the apparatus may employ another kind of patterning device as an alternative to the use of a classic mask; examples include a programmable mirror array or LCD matrix.

The source SO (e.g., a mercury lamp or excimer laser) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 23 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 23. However, in the case of a wafer stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

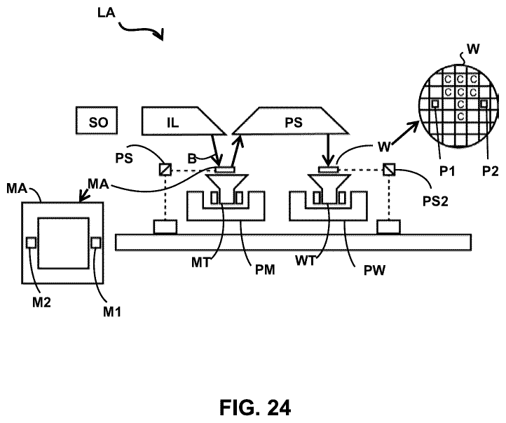

FIG. 24 schematically depicts another exemplary lithographic projection apparatus LA whose illumination source could be optimized utilizing the methods described herein.

The lithographic projection apparatus LA includes:
a source collector module SO
an illumination system (illuminator) IL configured to condition a radiation beam B (e.g. EUV radiation).
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus LA is of a reflective type (e.g. employing a reflective mask). It is to be noted that because most materials are absorptive within the EUV wavelength range, the mask may have multilayer reflectors comprising, for example, a multi-stack of Molybdenum and Silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 24, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 24, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LA could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.

3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

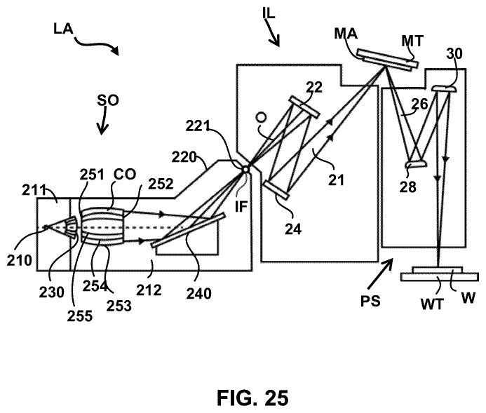

FIG. 25 shows the apparatus LA in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘0’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 25.

Collector optic CO, as illustrated in FIG. 25, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is preferably used in combination with a discharge produced plasma source, often called a DPP source.

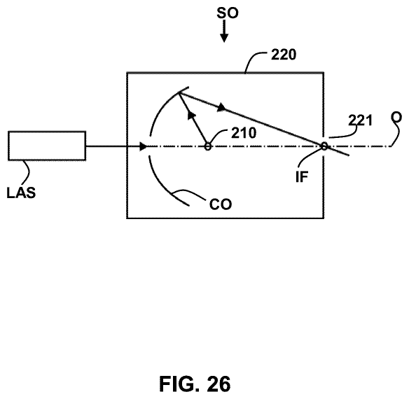

Alternatively, the source collector module SO may be part of an LPP radiation system as shown in FIG. 26. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

Embodiments of the present disclosure can be further described in the following clauses.

1. A method for determining a likelihood that an assist feature of a mask pattern will print on a substrate, the method comprising:

obtaining (i) a plurality of images of a pattern printed on a substrate, the images having been formed using the mask pattern and (ii) variance data associated with pixels of the plurality of images of the pattern;

determining, based on the variance data, a model configured to generate variance data associated with the mask pattern; and

determining, based on model-generated variance data for a given mask pattern and a resist image or etch image associated with the given mask pattern, the likelihood that an assist feature of the given mask pattern will be printed on the substrate, the likelihood being applied to adjust one or more parameters related to a patterning process or a patterning apparatus to reduce the likelihood that the assist feature will print on the substrate.

2. The method according to clause 1, wherein the obtaining of the plurality of images comprises:

receiving, via a metrology tool, the plurality of images of the pattern printed on the substrate; or

capturing, via the metrology tool, the plurality of images of the pattern printed on the substrate.

3. The method of clause 1, wherein:

the variance data is represented as another pixelated image, each pixel assigned a variance value of the grey scale values of each pixel of the plurality of images.

4. The method of any of clauses 1-3, wherein the determining of the model comprising:

inputting (i) an aerial image or a mask image associated with the mask pattern, and (ii) the variance data associated with the mask pattern to the model;

executing the model using initial values of model parameters to generate initial variance data;

determining a difference between the initial variance data and the inputted variance data; and

adjusting, based on the difference, the initial values of the model parameters to cause the model to generate variance data that is within a specified threshold of the inputted variance data.

5. The method of clause 4, wherein the determining of the model is an iterative process, wherein the adjusting of the values of the model parameters is performed until the model generated variance data is within the specified threshold of the inputted variance data.
6. The method of clause 5, wherein the adjusting of the initial values of the model parameters is based on a gradient of the difference between the outputted variance map and the inputted variance, the gradient guiding the values of the model parameters toward reducing or minimizing the difference.
7. The method of any of clauses 1-6, wherein the model is at least one of:

a convolutional neural network comprising weights and biases as model parameters,

a linear model comprising a combination of linear terms associated coefficients, the coefficients being the model parameters, and

a polynomial model comprising a combination of polynomial terms associated coefficients, the coefficients being the model parameters.

8. The method of any of clauses 1-7, wherein the determining of the likelihood that the assist feature of the given mask pattern will print on the substrate comprising:

obtaining, via a patterning process simulation or a metrology tool, the resist image associated with the given mask pattern;

establishing a correlation between the model-generated variance data and the resist image; and

identifying, based on the correlation, a region of the mask pattern or a target layout corresponding to the mask pattern that have a relatively higher likelihood of the assist feature being printed on the substrate.

9. The method of clause 8, wherein the establishing of the correlation between the model-generated variance data and the resist image comprising:

identifying, from the resist image, intensity values along a selected line on the resist image;

identifying, from the model-generated variance data, variance values corresponding to the selected line; and

correlating the identified variance values with the identified intensity values of the resist image along the selected line.

10. The method of clause 9, wherein the identifying of the region with relatively higher likelihood of the assist feature being printed on the substrate comprising:

determining, for one or more regions of the resist image, whether the intensity values breach a printing threshold associated with printing of a feature within a resist layer on the substrate;

determining, based on the correlation, whether the variance values corresponding to the one or more regions breach a specified variance threshold range;

responsive to the breaching of the specified variance threshold range, assigning a relatively higher probability of printing to portions of the one or more regions;

responsive to the breaching of the specified variance threshold range and not breaching of the printing threshold, assigning a relatively lower probability to portions of printing to the one or more regions;

responsive to not breaching of the specified variance threshold range and not breaching of the printing threshold, assigning a zero probability to portions of printing to the one or more regions; and

identifying the region from the one or more regions having greater than zero probability of printing, the region being surrounding a main pattern of the mask pattern.

11. The method of clause 10, wherein the printing threshold comprises:

an upper threshold value indicative of printing of a feature within the resist layer, and

a lower threshold value indicative of not printing of the feature the resist layer.

12. The method of clause 11, wherein values within the specified variance threshold range are indicative of not printing of a feature, and the values outside the specified variance threshold range are indicative of printing of the feature.
13. The method of any of clauses 1-12, further comprising:

generating, based on the model and the likelihood that the assist feature will print, optical proximity correction (OPC) data to adjust one or more main features, or one or more assist features of the mask pattern.

14. The method of clause 13, wherein the generating of the OPC data comprising:

adjusting, via an OPC simulation process associated with the patterning process, a shape and/or size of the one or more main features, or the one or more assist features of the mask pattern, the adjusted shape and/or size reducing the likelihood that an assist feature will print on the substrate; or

removing, via the OPC simulation process associated with the patterning process, the one or more assist features of the mask pattern.

15. The method of any of clauses 1-12, further comprising:

determining, based on the model and the likelihood that the assist feature will print, a source and/or a mask pattern to reduce the likelihood that an assist feature will print.

16. The method of clause 15 wherein the determining of the source and/or the mask pattern comprising:

adjusting, via a source mask optimization (SMO) process, source parameters and/or mask parameters to cause reduction in the likelihood that the assist feature of the mask pattern will print.

17. The method of any of clauses 1-12, further comprising:

adjusting, based on the model and the likelihood that the assist feature will print, one or more parameters of a patterning process used for patterning the substrate.

18. The method of any of clauses 17, wherein the adjusting of the one or more parameters of the patterning process comprising:

determining, using a mask image or an aerial image of a pattern being printed on the substrate as input the model, a likelihood that an assist feature will print on the substrate; and

adjusting the one or more parameters of the patterning process to reduce the likelihood that the assist feature will print on the substrate.

19. The method of clause 18, wherein the one or more parameters comprises: dose of a scanner, focus of the scanner, and/or a substrate table height.
20. A method for generating a model associated with a mask pattern, the method comprising:

obtaining (i) a plurality of images of a pattern printed on a substrate using the mask pattern, and (iii) variance data associated with each pixel of the plurality of images of the pattern; and

generating, based on the variance data, a model configured to predict variance data associated with the mask pattern, the variance data being used to determine a likelihood that an assist feature of the mask pattern will print on the substrate.

21. The method of clause 20, wherein the generating of the model comprising:

inputting (i) an aerial image or a mask image associated with the mask pattern, and (ii) and the variance data associated with the mask pattern to the model;

executing the model using initial values of model parameters to generate initial variance data;

determining a difference between the initial variance data and the inputted variance data; and

adjusting, based on the difference, the initial values of the model parameters to cause the model to generate the variance data that is within a specified threshold of the inputted variance data.

22. The method of clause 21, wherein the generating of the model is an iterative process, wherein the adjusting of the values of the model parameters is performed until the model generated variance data is within the specified threshold of the inputted variance data.
23. The method of clause 22, wherein the adjusting of the initial values of the model parameters is based on a gradient of the difference between the outputted variance map and the inputted variance, the gradient guiding the values of the model parameters toward reducing or minimizing the difference.
24. The method of any of clauses 20-23, wherein:

the variance data is represented as another pixelated image, each pixel assigned a variance value of the grey scale values of each pixel of the plurality of images.

25. The method of any of clauses 20-24, wherein the model is at least one of:

a convolutional neural network comprising weights and biases as model parameters,

a linear model comprising a combination of linear terms associated coefficients, the coefficients being the model parameters, and

a polynomial model comprising a combination of polynomial terms associated coefficients, the coefficients being the model parameters.

26. A method for generating optical proximity correction data for a mask pattern, the method comprising:

obtaining (i) a mask image or an aerial image associated with the mask pattern, and (ii) a resist image associated with the mask pattern;

executing a model configured to predict variance data associated with the mask pattern, the model using the mask image or the aerial image to predict the variance data;

determining, based on the variance data and the resist image, a likelihood that an assist feature of the mask pattern will print on a substrate; and

generating, based on the likelihood that the assist feature will print, the optical proximity correction (OPC) data for modifying one or more main features, or one or more assist features of the mask pattern.

27. The method of clause 26, wherein the generating of the OPC data comprising:

adjusting, via an OPC simulation process, a shape and/or size of the one or more main features, or the one or more assist features of the mask pattern, the adjusted shape and/or size reducing the likelihood that an assist feature will print; or

removing, via the OPC simulation process, the one or more assist features of the mask pattern.

28. The method of any of clauses 26-27, wherein the obtaining of the mask image or the aerial image comprises:

simulating one or more process models using the mask pattern to generate the mask image, or the aerial image.

29. The method of any of clauses 26-28, wherein the OPC data is used by a patterning device modification tool used to modify the mask pattern on a mask.
30. A non-transitory computer-readable media comprising instructions that, when executed by one or more processors, cause operations comprising:

obtaining (i) a plurality of images of a pattern printed on a substrate, the images having been formed using a mask pattern and (ii) variance data associated with pixels of the plurality of images of the pattern;

determining, based on the variance data, a model configured to generate variance data associated with the mask pattern; and

determining, based on model-generated variance data for a given mask pattern and a resist image or etch image associated with the given mask pattern, a likelihood that an assist feature of the given mask pattern will be printed on the substrate, the likelihood being applied to adjust one or more parameters related to a patterning process or a patterning apparatus to reduce the likelihood that the assist feature will print on the substrate.

31. The non-transitory computer-readable media according to clause 30, wherein the obtaining of the plurality of images comprises:

receiving, via a metrology tool, the plurality of images of the pattern printed on the substrate; or

capturing, via the metrology tool, the plurality of images of the pattern printed on the substrate.

32. The non-transitory computer-readable media of clause 30, wherein:

the variance data is represented as another pixelated image, each pixel assigned a variance value of the grey scale values of each pixel of the plurality of images.

33. The non-transitory computer-readable media of any of clauses 30-32, wherein the determining of the model comprising:

inputting (i) an aerial image or a mask image associated with the mask pattern, and (ii) the variance data associated with the mask pattern to the model;

executing the model using initial values of model parameters to generate initial variance data;

determining a difference between the initial variance data and the inputted variance data; and

adjusting, based on the difference, the initial values of the model parameters to cause the model to generate variance data that is within a specified threshold of the inputted variance data.

34. The non-transitory computer-readable media of clause 32, wherein the determining of the model is an iterative process, wherein the adjusting of the values of the model parameters is performed until the model generated variance data is within the specified threshold of the inputted variance data.
35. The non-transitory computer-readable media of clause 34, wherein the adjusting of the initial values of the model parameters is based on a gradient of the difference between the outputted variance map and the inputted variance, the gradient guiding the values of the model parameters toward reducing or minimizing the difference.
36. The non-transitory computer-readable media of any of clauses 30-35, wherein the model is at least one of:

a convolutional neural network comprising weights and biases as model parameters,

a linear model comprising a combination of linear terms associated coefficients, the coefficients being the model parameters, and

a polynomial model comprising a combination of polynomial terms associated coefficients, the coefficients being the model parameters.

37. The non-transitory computer-readable media of any of clauses 30-36, wherein the determining of the likelihood that the assist feature of the given mask pattern will print on the substrate comprising:

obtaining, via a patterning process simulation or a metrology tool, the resist image associated with the given mask pattern;

establishing a correlation between the model-generated variance data and the resist image; and

identifying, based on the correlation, a region of the mask pattern or a target layout corresponding to the mask pattern that have a relatively higher likelihood of the assist feature being printed on the substrate.

38. The non-transitory computer-readable media of clause 37, wherein the establishing of the correlation between the model-generated variance data and the resist image comprising:

identifying, from the resist image, intensity values along a selected line on the resist image;

identifying, from the model-generated variance data, variance values corresponding to the selected line; and

correlating the identified variance values with the identified intensity values of the resist image along the selected line.

39. The non-transitory computer-readable media of clause 38, wherein the identifying of the region with relatively higher likelihood of the assist feature being printed on the substrate comprising:

determining, for one or more regions of the resist image, whether the intensity values breach a printing threshold associated with printing of a feature within a resist layer on the substrate;

determining, based on the correlation, whether the variance values corresponding to the one or more regions breach a specified variance threshold range;

responsive to the breaching of the specified variance threshold range, assigning a relatively higher probability of printing to portions of the one or more regions;

responsive to the breaching of the specified variance threshold range and not breaching of the printing threshold, assigning a relatively lower probability to portions of printing to the one or more regions;

responsive to not breaching of the specified variance threshold range and not breaching of the printing threshold, assigning a zero probability to portions of printing to the one or more regions; and

identifying the region from the one or more regions having greater than zero probability of printing, the region being surrounding a main pattern of the mask pattern.

40. The non-transitory computer-readable media of clause 39, wherein the printing threshold comprises:

an upper threshold value indicative of printing of a feature within the resist layer, and a lower threshold value indicative of not printing of the feature the resist layer.

41. The non-transitory computer-readable media of clause 40, wherein values within the specified variance threshold range are indicative of not printing of a feature, and the values outside the specified variance threshold range are indicative of printing of the feature.
42. The non-transitory computer-readable media of any of clauses 30-41, further comprising:

generating, based on the model and the likelihood that the assist feature will print, optical proximity correction (OPC) data to adjust one or more main features, or one or more assist features of the mask pattern.

43. The non-transitory computer-readable media of clause 42, wherein the generating of the OPC data comprising:

adjusting, via an OPC simulation process associated with the patterning process, a shape and/or size of the one or more main features, or the one or more assist features of the mask pattern, the adjusted shape and/or size reducing the likelihood that an assist feature will print on the substrate; or

removing, via the OPC simulation process associated with the patterning process, the one or more assist features of the mask pattern.

44. The non-transitory computer-readable media of any of clauses 30-42, further comprising:

determining, based on the model and the likelihood that the assist feature will print, a source and/or a mask pattern to reduce the likelihood that an assist feature will print.

45. The non-transitory computer-readable media of clause 44 wherein the determining of the source and/or the mask pattern comprising:

adjusting, via a source mask optimization (SMO) process, source parameters and/or mask parameters to cause reduction in the likelihood that the assist feature of the mask pattern will print.

46. The non-transitory computer-readable media of any of clauses 30-42, further comprising:

adjusting, based on the model and the likelihood that the assist feature will print, one or more parameters of a patterning process used for patterning the substrate.

47. The non-transitory computer-readable media of clause 46, wherein the adjusting of the one or more parameters of the patterning process comprising:

determining, using a mask image or an aerial image of a pattern being printed on the substrate as input the model, a likelihood that an assist feature will print on the substrate; and

adjusting the one or more parameters of the patterning process to reduce the likelihood that the assist feature will print on the substrate.

48. The non-transitory computer-readable media of clause 47, wherein the one or more parameters comprises: dose of a scanner, focus of the scanner, and/or a substrate table height.
49. A non-transitory computer-readable media comprising instructions that, when executed by one or more processors, cause operations comprising:

obtaining (i) a plurality of images of a pattern printed on a substrate using a mask pattern, and (iii) variance data associated with each pixel of the plurality of images of the pattern; and

generating, based on the variance data, a model configured to predict variance data associated with the mask pattern, the variance data being used to determine a likelihood that an assist feature of the mask pattern will print on the substrate.

50. The non-transitory computer-readable media of clause 49, wherein the generating of the model comprising:

inputting (i) an aerial image or a mask image associated with the mask pattern, and (ii) and the variance data associated with the mask pattern to the model;

executing the model using initial values of model parameters to generate initial variance data;

determining a difference between the initial variance data and the inputted variance data; and

adjusting, based on the difference, the initial values of the model parameters to cause the model to generate the variance data that is within a specified threshold of the inputted variance data.

51. The non-transitory computer-readable media of clause 50, wherein the generating of the model is an iterative process, wherein the adjusting of the values of the model parameters is performed until the model generated variance data is within the specified threshold of the inputted variance data.
52. The non-transitory computer-readable media of clause 51, wherein the adjusting of the initial values of the model parameters is based on a gradient of the difference between the outputted variance map and the inputted variance, the gradient guiding the values of the model parameters toward reducing or minimizing the difference.
53. The non-transitory computer-readable media of any of clauses 49-52, wherein:

the variance data is represented as another pixelated image, each pixel assigned a variance value of the grey scale values of each pixel of the plurality of images.

54. The non-transitory computer-readable media of any of clauses 49-53, wherein the model is at least one of:

a convolutional neural network comprising weights and biases as model parameters,

a linear model comprising a combination of linear terms associated coefficients, the coefficients being the model parameters, and

a polynomial model comprising a combination of polynomial terms associated coefficients, the coefficients being the model parameters.

55. A non-transitory computer-readable media comprising instructions that, when executed by one or more processors, cause operations comprising:

obtaining (i) a mask image or an aerial image associated with the mask pattern, and (ii) a resist image associated with a mask pattern;

executing a model configured to predict variance data associated with the mask pattern, the model using the mask image or the aerial image to predict the variance data;

determining, based on the variance data and the resist image, a likelihood that an assist feature of the mask pattern will print on a substrate; and

generating, based on the likelihood that the assist feature will print, optical proximity correction (OPC) data for modifying one or more main features, or one or more assist features of the mask pattern.

56. The non-transitory computer-readable media of clause 55, wherein the generating of the OPC data comprising:

adjusting, via an OPC simulation process, a shape and/or size of the one or more main features, or the one or more assist features of the mask pattern, the adjusted shape and/or size reducing the likelihood that an assist feature will print; or

removing, via the OPC simulation process, the one or more assist features of the mask pattern.

57. The non-transitory computer-readable media of any of clauses 55-56, wherein the obtaining of the mask image or the aerial image comprises:

simulating one or more process models using the mask pattern to generate the mask image, or the aerial image.

58. The non-transitory computer-readable media of any of clauses 55-57, wherein the OPC data is used by a patterning device modification tool used to modify the mask pattern on a mask.
59. A non-transitory computer-readable media comprising instructions for generating a printability map associated with a mask pattern that, the computer-readable media when executed by one or more processors, cause operations comprising:

obtaining (i) a plurality of images of a patterned substrate, (ii) a plurality of refined images based on the plurality of images, and (iii) a simulated refined image based on the mask pattern;

marking each of the plurality of images based on the plurality of the refined images, the simulated refined image, and an intensity of pixels within each of the plurality of images; and

generating, based on the markings, the printability map associated with the mask pattern.

60. The non-transitory computer-readable media of clause 59, wherein the marking of each of the plurality of images comprises:

aligning a refined image of the plurality of the refined images with the simulated refined image;

identifying features within the refined image that correspond to features within the simulated refined image;

aligning an image of the plurality of image with the aligned refined image; and

placing, based on the identified features, markers on the aligned image, each marker being placed at a location associated with a local minima of the intensity within the image around the identified feature.

61. The non-transitory computer-readable media of clause 60, wherein the placing of the markers comprises:

determining a contour of an identified feature within the refined image;

aligning the contour with a corresponding feature in the image of the plurality of images; and

identifying locations of a pair of markers around the contour, a first marker is at a local minima of image intensity inside the contour, and a second marker is another local minima of the image intensity outside the contour.

62. The non-transitory computer-readable media of clause 61, wherein the identifying of the pair of markers comprises:

determining the first marker, in a specified direction toward the inside of the contour, the local minima of the intensity of the image; and

determining the second marker, in the specified direction toward the outside of the contour and across a local maxima of the intensity of the image, another local minima of the intensity of the image.

63. The non-transitory computer-readable media of any of clauses 59-62, wherein the generating of the printability map comprises:

inputting the marks of the plurality of images to an algorithm configured to generate a plurality of another refined images corresponding to each image of the plurality of images;

aligning the plurality of another refined images with respect to each other; and

generating, based on intensity values of the aligned plurality of another refined images, the printability map for at least one of the plurality of another refined images.

64. The non-transitory computer-readable media of clause 63, wherein the generating of the printability map comprises:

determining a probability value of each pixel of the printability map by:
summing the image intensity of another refined images of the plurality of refined images; and
dividing the image intensity of the summed image by the total number of refined images.
   65. The non-transitory computer-readable media of any of clauses 62-64, wherein the algorithm is

a watershed algorithm configured to perform image segmentation based on the markers placed within the plurality of images.

66. The non-transitory computer-readable media of any of clauses 59-65, the obtaining of the plurality of images comprises:

receiving, via a metrology tool, the plurality of images of the pattern printed on the substrate; or

capturing, via the metrology tool, the plurality of images of the pattern printed on the substrate.

67. The non-transitory computer-readable media of any of clauses 59-66, wherein the obtaining of the plurality of refined images comprise:

denoising the plurality of images; and

converting, via an adaptive thresholding algorithm, each of the denoised plurality of images to a refined image, the adaptive thresholding algorithm adaptively finding an optimal threshold to distinguish printing and not printing areas within an image.

68. The non-transitory computer-readable media of clause 67, wherein the adaptive thresholding algorithm is an Otsu thresholding algorithm configured to receive the plurality of images or the denoised plurality of images and the markers within each of the plurality of images as input and output a refined image.
69. The non-transitory computer-readable media of any of clauses 66-68, wherein the denoising of the plurality of images comprises:

applying a first median filter and a Gaussian filter to each of the plurality of images to such that a ridge edge accuracy associated with each of the plurality of images is maintained, the first median filter characterized by a first kernel size;

applying a second median filter to enhance image contrast of each of the plurality of images, the image contrast being between printing area and not printing area, the second median filter characterized by a second kernel size, the second kernel size being greater than the first kernel size; and

applying a third filter to further decrease noise in the plurality of images, the third filter characterized by a third kernel size.

70. The non-transitory computer-readable media of any of clauses 59-69, wherein the obtaining of the simulated refined image comprises:

executing one or more process models of the patterning process using the mask pattern and process conditions corresponding to each of the plurality of images to generate the simulated image of a pattern that will be printed on a substrate; and

applying a selected threshold intensity value to the simulated image to generate the simulated refined image.

71. The non-transitory computer-readable media of any of clauses 59-70, further comprising generating values of one or more parameters of the patterning process based on the printability map.
72. The non-transitory computer-readable media of clause 71, wherein the generating comprising:

inputting the printability map associated with the mask pattern. to an optical proximity correction process;

determining a probability associated an assist feature of the mask pattern from the printability map, the probability indicative of whether the assist feature will print on a substrate; and

generating, based on the probability of the assist feature, optical proximity correction (OPC) data to adjust one or more main features, or one or more assist features of the mask pattern to minimize the probability that the assist feature will print on the substrate.

73. The non-transitory computer-readable media of clause 72, wherein the generating of the OPC data comprising:

adjust, via the OPC simulation process associated with the patterning process, a shape and/or size of the one or more main features, or the one or more assist features of the mask pattern, the adjusted shape and/or size reducing the probability that an assist feature will print on the substrate; or

remove, via the OPC simulation process associated with the patterning process, the one or more assist features of the mask pattern.

74. The non-transitory computer-readable media of clause 71, wherein the generating comprising:

determining, based on the printability map, parameters associated with a source and/or a mask pattern to reduce the probability that an assist feature will print.

75. The non-transitory computer-readable media of clause 74, wherein the determining of the source and/or the mask pattern comprises:

adjusting, via a source mask optimization (SMO) process, source parameters and/or mask parameters to cause reduction in the probability that the assist feature of the mask pattern will print on the substrate.

76. The non-transitory computer-readable media of clause 71, wherein the generating comprising:

adjusting, based on the printability map, one or more parameters associated with a patterning apparatus used for patterning the substrate to cause a reduction in the probability that an assist feature will print on the substrate.

77. The non-transitory computer-readable media of clause 76, wherein the one or more parameters comprises: dose of a scanner, focus of the scanner, and/or a substrate table height.
78. The non-transitory computer-readable media of any of clauses 59-77, wherein one or more refined images of the plurality of refined images are one or more binary images.
79. The non-transitory computer-readable media of any of clauses 59-78, wherein the simulated refined image is a binary image.
80. The non-transitory computer-readable media of any of clauses 59-79, wherein the printability map is a spatial distribution of probability values indicating likelihood that features of the pattern will be printed on a substrate.
81. The non-transitory computer-readable media of any of clauses 59-80, wherein the plurality of images are obtained via a scanning electron microscope (SEM) of a patterned substrate.
82. The non-transitory computer-readable media of clause 81, wherein each image of the plurality of images is a SEM image.
83. A method for generating a printability map associated with a mask pattern, the method comprising:

obtaining (i) a plurality of images of a patterned substrate, (ii) a plurality of refined images based on the plurality of images, and (iii) a simulated refined image based on the mask pattern;

marking each of the plurality of images based on the plurality of the refined images, the simulated refined image, and an intensity of pixels within each of the plurality of images; and

generating, based on the markings, the printability map associated with the mask pattern.

84. The method of clause 83, wherein the marking of each of the plurality of images comprises:

aligning a refined image of the plurality of the refined images with the simulated refined image;

identifying features within the refined image that correspond to features within the simulated refined image;

aligning an image of the plurality of image with the aligned refined image; and

placing, based on the identified features, markers on the aligned image, each marker being placed at a location associated with a local minima of the intensity within the image around the identified feature.

85. The method of clause 84, wherein the placing of the markers comprises:

determining a contour of an identified feature within the refined image;

aligning the contour with a corresponding feature in the image of the plurality of images; and

identifying locations of a pair of markers around the contour, a first marker is at a local minima of image intensity inside the contour, and a second marker is another local minima of the image intensity outside the contour.

86. The method of clause 84, wherein the identifying of the pair of markers comprises:

determining the first marker, in a specified direction toward the inside of the contour, the local minima of the intensity of the image; and

determining the second marker, in the specified direction toward the outside of the contour and across a local maxima of the intensity of the image, another local minima of the intensity of the image.

87. The method of any of clauses 83-86, wherein the generating of the printability map comprises:

inputting the marks of the plurality of images to an algorithm configured to generate a plurality of another refined images corresponding to each image of the plurality of images;

aligning the plurality of another refined images with respect to each other; and

generating, based on intensity values of the aligned plurality of another refined images, the printability map for at least one of the plurality of another refined images.

88. The method of clause 63, wherein the generating of the printability map comprises:

determining a probability value of each pixel of the printability map by:

summing the image intensity of another refined images of the plurality of refined images; and

dividing the image intensity of the summed image by the total number of refined images.

89. The method of any of clauses 86-88, wherein the algorithm is a watershed algorithm configured to perform image segmentation based on the markers placed within the plurality of images.
90. The method of any of clauses 83-89, the obtaining of the plurality of images comprises:

receiving, via a metrology tool, the plurality of images of the pattern printed on the substrate; or

capturing, via the metrology tool, the plurality of images of the pattern printed on the substrate.

91. The method of any of clauses 83-90, wherein the obtaining of the plurality of refined images comprise:

denoising the plurality of images; and

converting, via an adaptive thresholding algorithm, each of the denoised plurality of images to a refined image, the adaptive thresholding algorithm adaptively finding an optimal threshold to distinguish printing and not printing areas within an image.

92. The method of clause 91, wherein the adaptive thresholding algorithm is an Otsu thresholding algorithm configured to receive the plurality of images or the denoised plurality of images and the markers within each of the plurality of images as input and output a refined image.
93. The method of any of clauses 90-92, wherein the denoising of the plurality of images comprises:

applying a first median filter and a Gaussian filter to each of the plurality of images to such that a ridge edge accuracy associated with each of the plurality of images is maintained, the first median filter characterized by a first kernel size;

applying a second median filter to enhance image contrast of each of the plurality of images, the image contrast being between printing area and not printing area, the second median filter characterized by a second kernel size, the second kernel size being greater than the first kernel size; and

applying a third filter to further decrease noise in the plurality of images, the third filter characterized by a third kernel size.

94. The method of any of clauses 83-93, wherein the obtaining of the simulated refined image comprises:

executing one or more process models of the patterning process using the mask pattern and process conditions corresponding to each of the plurality of images to generate the simulated image of a pattern that will be printed on a substrate; and

applying a selected threshold intensity value to the simulated image to generate the simulated refined image.

95. The method of any of clauses 83-94, further comprising generating values of one or more parameters of the patterning process based on the printability map.
96. The method of clause 95, wherein the generating comprising:

inputting the printability map associated with the mask pattern. to an optical proximity correction process;

determining a probability associated an assist feature of the mask pattern from the printability map, the probability indicative of whether the assist feature will print on a substrate; and

generating, based on the probability of the assist feature, optical proximity correction (OPC) data to adjust one or more main features, or one or more assist features of the mask pattern to minimize the probability that the assist feature will print on the substrate.

97. The method of clause 96, wherein the generating of the OPC data comprising:

adjust, via the OPC simulation process associated with the patterning process, a shape and/or size of the one or more main features, or the one or more assist features of the mask pattern, the adjusted shape and/or size reducing the probability that an assist feature will print on the substrate; or

remove, via the OPC simulation process associated with the patterning process, the one or more assist features of the mask pattern.

98. The method of clause 95, wherein the generating comprising:

determining, based on the printability map, parameters associated with a source and/or a mask pattern to reduce the probability that an assist feature will print.

99. The method of clause 98, wherein the determining of the source and/or the mask pattern comprises:

adjusting, via a source mask optimization (SMO) process, source parameters and/or mask parameters to cause reduction in the probability that the assist feature of the mask pattern will print on the substrate.

100. The method of clause 95, wherein the generating comprising:

adjusting, based on the printability map, one or more parameters associated with a patterning apparatus used for patterning the substrate to cause a reduction in the probability that an assist feature will print on the substrate.

101. The method of clause 100, wherein the one or more parameters comprises: dose of a scanner, focus of the scanner, and/or a substrate table height.
102. The method of any of clauses 83-101, wherein one or more refined images of the plurality of refined images are one or more binary images.
103. The method of any of clauses 83-102, wherein the simulated refined image is a binary image.
104. The method of any of clauses 83-102, wherein the printability map is a spatial distribution of probability values indicating likelihood that features of the pattern will be printed on a substrate.
105. The method of any of clauses 83-104, wherein the plurality of images are obtained via a scanning electron microscope (SEM) of a patterned substrate.
106. The method of clause 105, wherein each image of the plurality of images is a SEM image.
107. A non-transitory computer-readable media comprising instructions for generating a printability map associated with a mask pattern that, the computer-readable media when executed by one or more processors, cause operations comprising:

obtaining a plurality of refined images of a patterned substrate based on markings of a plurality of images of a patterned substrate, the markings of each image of the plurality of images being associated with an intensity of a pixel of the each image;

summing image intensities of the plurality of refined images; and

dividing the summed image intensities by the total number of refined images to generate the printability map associated with the mask pattern.

108. The non-transitory computer-readable media of clause 107, wherein the obtaining of the plurality of refined images comprises:

inputting the marks of the plurality of images to an algorithm configured to generate the plurality of refined images corresponding to each image of the plurality of images.

109. The non-transitory computer-readable media of clause 108, wherein the algorithm is a watershed algorithm configured to perform image segmentation based on the markers placed within the plurality of images.
110. The non-transitory computer-readable media of clause 109, wherein the marking of each of the plurality of images comprises:

aligning a binarized image of the plurality of the images with a simulated refined image;

identifying features within the binarized image that correspond to features within the simulated refined image;

aligning an image of the plurality of image with the aligned binarized image; and

placing, based on the identified features, markers on the aligned image, each marker being placed at a location associated with a local minima of the intensity within the image around the identified feature.

111. The non-transitory computer-readable media of clause 110, wherein the placing of the markers comprises:

determining a contour of an identified feature within the binarized image;

aligning the contour with a corresponding feature in the image of the plurality of images; and

identifying locations of a pair of markers around the contour, a first marker is at a local minima of image intensity inside the contour, and a second marker is another local minima of the image intensity outside the contour.

112. The non-transitory computer-readable media of clause 111, wherein the identifying of the pair of markers comprises:

determining the first marker, in a specified direction toward the inside of the contour, the local minima of the intensity of the image; and

determining the second marker, in the specified direction toward the outside of the contour and across a local maxima of the intensity of the image, another local minima of the intensity of the image.

113. A method for generating a printability map associated with a mask pattern, the method comprising:

obtaining a plurality of refined images of a patterned substrate based on markings of a plurality of images of a patterned substrate, the markings of each image of the plurality of images being associated with an intensity of a pixel of the each image;

summing image intensities of the plurality of refined images; and

dividing the summed image intensities by the total number of refined images to generate the printability map associated with the mask pattern.

114. The method of clause 113, wherein the obtaining of the plurality of refined images comprises:

inputting the marks of the plurality of images to an algorithm configured to generate the plurality of refined images corresponding to each image of the plurality of images.

115. The method of clause 114, wherein the algorithm is a watershed algorithm configured to perform image segmentation based on the markers placed within the plurality of images.
116. The method of clause 115, wherein the marking of each of the plurality of images comprises:

aligning a binarized image of the plurality of the images with a simulated refined image;

identifying features within the binarized image that correspond to features within the simulated refined image;

aligning an image of the plurality of image with the aligned binarized image; and

placing, based on the identified features, markers on the aligned image, each marker being placed at a location associated with a local minima of the intensity within the image around the identified feature.

117. The method of clause 116, wherein the placing of the markers comprises:

determining a contour of an identified feature within the binarized image;

aligning the contour with a corresponding feature in the image of the plurality of images; and

identifying locations of a pair of markers around the contour, a first marker is at a local minima of image intensity inside the contour, and a second marker is another local minima of the image intensity outside the contour.

118. The method of clause 117, wherein the identifying of the pair of markers comprises:

determining the first marker, in a specified direction toward the inside of the contour, the local minima of the intensity of the image; and

determining the second marker, in the specified direction toward the outside of the contour and across a local maxima of the intensity of the image, another local minima of the intensity of the image.

119. A non-transitory computer-readable media comprising instructions for generating a printability map associated with a mask pattern that, the computer-readable media when executed by one or more processors, cause operations comprising:

obtaining a plurality of binary images of a patterned substrate based on features of the mask pattern;

aligning the plurality of binary images and summing intensities of the plurality of binary images; and

dividing the summed image intensities by the total number of binary images to generate the printability map associated with the mask pattern, wherein each pixel intensity of the printability map is indicative of a probability that a feature of the mask pattern will print on a substrate.

120. The non-transitory computer-readable media of clause 119, wherein the obtaining of the plurality of binary images comprises:

applying a binarization algorithm to each of a plurality of images of the patterned substrate, the binarization algorithm being configured to generate a binary image for a given image of the plurality of images based on features in the given image that correspond to the features of the mask pattern.

121. The non-transitory computer-readable media of clause 120, wherein the features within each of the plurality of images corresponding features of the mask pattern are identified based on a simulated image of the patterned substrate.
122. The non-transitory computer-readable media of clause 121, wherein the binarization algorithm comprises thresholding of each of the plurality of images of the patterned substrate, the thresholding being based on the features corresponding to the mask pattern.
123. The non-transitory computer-readable media of clause 121, wherein the binarization algorithm is a watershed algorithm configured to perform image segmentation based on markers placed within the plurality of images.
124. The non-transitory computer-readable media of clause 122, wherein the markers comprises:

a first marker, in a specified direction toward the inside of the contour, a local minima of the intensity of the image; and

a second marker, in the specified direction toward the outside of the contour and across a local maxima of the intensity of the image, another local minima of the intensity of the image.

125. A method comprising instructions for generating a printability map associated with a mask pattern, the method comprising:

obtaining a plurality of binary images of a patterned substrate based on features of the mask pattern;

aligning the plurality of binary images and summing intensities of the plurality of binary images; and

dividing the summed image intensities by the total number of binary images to generate the printability map associated with the mask pattern, wherein each pixel intensity of the printability map is indicative of a probability that a feature of the mask pattern will print on a substrate.

126. The method of clause 125, wherein the obtaining of the plurality of binary images comprises:

applying a binarization algorithm to each of a plurality of images of the patterned substrate, the binarization algorithm being configured to generate a binary image for a given image of the plurality of images based on features in the given image that correspond to the features of the mask pattern.

127. The method of clause 126, wherein the features within each of the plurality of images corresponding features of the mask pattern are identified based on a simulated image of the patterned substrate.
128. The method of clause 127, wherein the binarization algorithm comprises thresholding of each of the plurality of images of the patterned substrate, the thresholding being based on the features corresponding to the mask pattern.
129. The method of clause 127, wherein the binarization algorithm is a watershed algorithm configured to perform image segmentation based on markers placed within the plurality of images.
130. The method of clause 129, wherein the markers comprises:

a first marker, in a specified direction toward the inside of the contour, a local minima of the intensity of the image; and

a second marker, in the specified direction toward the outside of the contour and across a local maxima of the intensity of the image, another local minima of the intensity of the image.

The descriptions above are intended to be illustrative, not limiting. Thus, it will be apparent to one skilled in the art that modifications may be made as described without departing from the scope of the claims set out below.

1. A method comprising:
obtaining (i) a plurality of images of a pattern printed on a substrate, the images having been formed using a mask pattern and (ii) variance data associated with pixels of the plurality of images of the pattern;
determining, based on the variance data, a model configured to generate variance data associated with the mask pattern; and
determining, by a hardware computer and based on model-generated variance data for a given mask pattern and on a resist image or etch image associated with the given mask pattern, a likelihood that an assist feature of the given mask pattern will be printed on a substrate, the likelihood configured to be applied to adjust one or more parameters related to a patterning process or a patterning apparatus to reduce the likelihood that the assist feature will print on the substrate.

2. The method according to claim 1, wherein the obtaining of the plurality of images comprises:
receiving, from a metrology tool, the plurality of images of the pattern printed on the substrate; or
capturing, from the metrology tool, the plurality of images of the pattern printed on the substrate.

3. The method of claim 1, wherein the variance data is represented as another pixelated image, each pixel assigned a variance value of grey scale values of each pixel of the plurality of images.

4. The method of claim 1, wherein the determining of the model comprises:
inputting (i) an aerial image or a mask image associated with the mask pattern, and (ii) the variance data associated with the mask pattern, to the model;
executing the model using initial values of model parameters to generate initial variance data;
determining a difference between the initial variance data and the inputted variance data; and
adjusting, based on the difference, a value of one or more of the model parameters to cause the model to generate variance data that is within a specified threshold of the inputted variance data.

5. The method of claim 4, wherein the determining of the model is an iterative process, wherein the adjusting of a value of one or more of the model parameters is performed until the model generated variance data is within the specified threshold of the inputted variance data.

6. The method of claim 5, wherein the adjusting of a value of one or more of the model parameters is based on a gradient of a difference between an outputted variance map and the inputted variance, the gradient guiding the value of the one or more model parameters toward reducing or minimizing the difference.

7. The method of claim 1, wherein the model is at least one selected from:
a machine learning neural network comprising weights and biases as model parameters,
a linear model comprising a combination of linear terms associated coefficients, the coefficients being model parameters, and/or
a polynomial model comprising a combination of polynomial terms associated coefficients, the coefficients being model parameters.

8. The method of claim 1, wherein the determining of the likelihood that the assist feature of the given mask pattern will be printed comprises:
obtaining, from a patterning process simulation or a metrology tool, a resist image associated with the given mask pattern;
establishing a correlation between the model-generated variance data and the resist image; and
identifying, based on the correlation, a region of the mask pattern or a target layout corresponding to the mask pattern, that has a relatively higher likelihood of the assist feature being printed on the substrate.

9. The method of claim 8, wherein the establishing of the correlation between the model-generated variance data and the resist image comprises:
identifying, from the resist image, intensity values along a selected line on the resist image;
identifying, from the model-generated variance data, variance values corresponding to the selected line; and
correlating the identified variance values with the identified intensity values of the resist image along the selected line.

10. The method of claim 8, wherein the identifying of the region with relatively higher likelihood of the assist feature being printed on the substrate comprises:
determining, for one or more regions of the resist image, whether the intensity values breach a printing threshold associated with printing of a feature within a resist layer on the substrate;
determining, based on the correlation, whether the variance values corresponding to the one or more regions breach a specified variance threshold range;
responsive to the breaching of the specified variance threshold range and breaching of the printing threshold, assigning a relatively higher probability of printing to portions of the one or more regions;
responsive to the breaching of the specified variance threshold range and not breaching of the printing threshold, assigning a relatively lower probability of printing to portions of the one or more regions;
responsive to not breaching of the specified variance threshold range and not breaching of the printing threshold, assigning a zero probability of printing to portions of the one or more regions; and
identifying the region from the one or more regions having greater than zero probability of printing, the region being surrounding a main pattern of the mask pattern.

11. The method of claim 10, wherein the printing threshold comprises:
an upper threshold value indicative of printing of a feature within the resist layer, and
a lower threshold value indicative of not printing of the feature within the resist layer.

12. The method of claim 1, further comprising generating, based on the model and the likelihood that the assist feature will print, optical proximity correction (OPC) data to adjust one or more main features or one or more assist features, of the mask pattern.

13. The method of claim 1, further comprising determining, based on the model and the likelihood that the assist feature will print, an illumination and/or a mask pattern to reduce the likelihood that an assist feature will print.

14. The method of claim 1, further comprising adjusting, based on the model and the likelihood that the assist feature will print, one or more parameters of a patterning process or a patterning apparatus used for patterning the substrate.

15. A non-transitory computer-readable media comprising instructions that, when executed by one or more processors, are configured to cause the one or more processors to at least:
obtain (i) a plurality of images of a pattern printed on a substrate, the images having been formed using a mask pattern and (ii) variance data associated with pixels of the plurality of images of the pattern;
determine, based on the variance data, a model configured to generate variance data associated with the mask pattern; and
determine, based on model-generated variance data for a given mask pattern and on a resist image or etch image associated with the given mask pattern, a likelihood that an assist feature of the given mask pattern will be printed on a substrate, the likelihood configured to be applied to adjust one or more parameters related to a patterning process or a patterning apparatus to reduce the likelihood that the assist feature will print on the substrate.

16. The media of claim 15, wherein the variance data is represented as another pixelated image, each pixel assigned a variance value of grey scale values of each pixel of the plurality of images.

17. The media of claim 15, wherein the instructions are further configured to cause the one or more processors to:
input (i) an aerial image or a mask image associated with the mask pattern, and (ii) the variance data associated with the mask pattern, to the model;
execute the model using initial values of model parameters to generate initial variance data;
determine a difference between the initial variance data and the inputted variance data; and
adjust, based on the difference, a value of one or more of the model parameters to cause the model to generate variance data that is within a specified threshold of the inputted variance data.

18. The media of claim 15, wherein the instructions configured to cause the one or more processors to determine the likelihood that the assist feature of the given mask pattern will be printed are further configured to cause the one or more processors to:
obtain, from a patterning process simulation or a metrology tool, a resist image associated with the given mask pattern;
establish a correlation between the model-generated variance data and the resist image; and
identify, based on the correlation, a region of the mask pattern or a target layout corresponding to the mask pattern, that has a relatively higher likelihood of the assist feature being printed on the substrate.

19. The media of claim 15, wherein the instructions configured to cause the one or more processors to establish the correlation between the model-generated variance data and the resist image are further configured to cause the one or more processors to:
identify, from the resist image, intensity values along a selected line on the resist image;
identify, from the model-generated variance data, variance values corresponding to the selected line; and
correlate the identified variance values with the identified intensity values of the resist image along the selected line.

20. The media of claim 15, wherein the instructions configured to cause the one or more processors to identify the region with relatively higher likelihood of the assist feature being printed on the substrate are further configured to cause the one or more processors to:
determine, for one or more regions of the resist image, whether intensity values breach a printing threshold associated with printing of a feature within a resist layer on the substrate;
determine, based on the correlation, whether the variance values corresponding to the one or more regions breach a specified variance threshold range;
responsive to the breaching of the specified variance threshold range and breaching of the printing threshold, assign a relatively higher probability of printing to portions of the one or more regions;
responsive to the breaching of the specified variance threshold range and not breaching of the printing threshold, assign a relatively lower probability of printing to portions of the one or more regions;
responsive to not breaching of the specified variance threshold range and not breaching of the printing threshold, assign a zero probability of printing to portions of the one or more regions; and
identify the region from the one or more regions having greater than zero probability of printing, the region being surrounding a main pattern of the mask pattern.
